(19) United States
(12) Patent Application Publication
(10) Pub. No.: US 2024/0196680 A1
(43) Pub. Date: Jun. 13, 2024

(54) ARRAY SUBSTRATE, DISPLAY PANEL, AND DISPLAY APPARATUS

(71) Applicants: Wuhan Tianma Microelectronics Co., Ltd., Wuhan (CN); Wuhan Tianma Microelectronics Co., Ltd. Shanghai Branch, Shanghai (CN)

(72) Inventors: Huiping CHAI, Wuhan (CN); Lin ZHANG, Wuhan (CN); Gaojun HUANG, Wuhan (CN)

(73) Assignees: Wuhan Tianma Microelectronics Co., Ltd., Wuhan (CN); Wuhan Tianma Microelectronics Co., Ltd. Shanghai Branch, Shanghai (CN)

(21) Appl. No.: 18/582,823

(22) Filed: Feb. 21, 2024

(30) Foreign Application Priority Data
Feb. 22, 2023 (CN) 202310162909.6

(51) Int. Cl. H10K 59/131; H10K 59/121; H10K 59/123; H10K 59/88

(52) U.S. Cl. CPC H10K 59/131; H10K 59/1213; H10K 59/123; H10K 59/88

(57) ABSTRACT

Provided are an array substrate, a display panel, and a display apparatus. The array substrate includes a display region, a substrate, pixel driving circuits, and scanning signal lines. The display region includes a plurality of pixel regions. At least part of a pixel driving circuit and at least part of a scanning signal line are located in the display region and on the same side of the substrate. The scanning signal line extends in a first direction. At least part of the pixel driving circuit is located in a pixel region and includes thin-film transistors. A thin-film transistor includes a gate and a channel layer. The gate is a portion where the scanning signal line overlaps the channel layer. The array substrate further includes auxiliary signal lines. An auxiliary signal line is located in the display region and extends in the first direction.

### CROSS-REFERENCE TO RELATED APPLICATION(S)

This application claims priority to Chinese Patent Application No. 202310162909.6 filed Feb. 22, 2023, the disclosure of which is incorporated herein by reference in its entirety.

### TECHNICAL FIELD

The present disclosure relates to the field of display technology and, in particular, to an array substrate, a display panel, and a display apparatus.

### BACKGROUND

With the development of science and technology, more and more display apparatuses, such as mobile phones, tablet computers, laptops and smart wearable devices, are widely applied to people's daily life and work, bringing great convenience to people's daily life and work and becoming an essential important tool for people today. A display panel is a main component of a display apparatus for implementing a display function.

In the display panel, a pixel driving circuit provides a drive current required by the display of a light-emitting element of the display panel and controls whether the light-emitting element enters a light emission stage, thereby becoming an indispensable element in most self-luminous display panels.

### SUMMARY

The present disclosure provides an array substrate, a display panel, and a display apparatus, reducing the transmission voltage drop of a scanning signal and improving the display performance.

In a first aspect, an embodiment of the present disclosure provides an array substrate. The array substrate includes a display region, a substrate, pixel driving circuits, and scanning signal lines. The display region includes a plurality of pixel regions.

At least part of a pixel driving circuit among the pixel driving circuits and at least part of a scanning signal line among the scanning signal lines are located in the display region and on a same side of the substrate. The scanning signal line extends in a first direction.

At least part of the pixel driving circuit is located in a pixel region among the plurality of pixel regions and includes thin-film transistors. A thin-film transistor among the thin-film transistors includes a gate and a channel layer. The gate is a portion where the scanning signal line overlaps the channel layer.

The array substrate further includes auxiliary signal lines. An auxiliary signal line among the auxiliary signal lines is located in the display region and extends in the first direction. A resistance of the auxiliary signal line is smaller than a resistance of the scanning signal line. The auxiliary signal line and the scanning signal line are disposed in different layers. The auxiliary signal line is electrically connected to the scanning signal line through a line exchanging through hole.

In a second aspect, an embodiment of the present disclosure provides a display panel. The display panel includes the array substrate described in the first aspect and a plurality of light-emitting elements.

A light-emitting element among the plurality of light-emitting elements is electrically connected to a pixel driving circuit and is configured to be driven by the pixel driving circuit to emit light.

In a third aspect, an embodiment of the present disclosure provides a display apparatus. The display apparatus includes the display panel described in the second aspect.

For the array substrate according to an embodiment of the present disclosure, the gate control signal lines include the scanning signal lines and the auxiliary signal lines. The auxiliary signal lines are provided for the scanning signal lines. The resistance of the auxiliary signal line is smaller than the resistance of the scanning signal line. The auxiliary signal line is electrically connected to the scanning signal line through the line exchanging through hole.

### BRIEF DESCRIPTION OF DRAWINGS

FIG. 1 is a top view of an array substrate according to an embodiment of the present disclosure.

FIG. 2 is a diagram illustrating a circuit structure of a pixel driving circuit according to an embodiment of the present disclosure.

FIG. 3 is a top view of a pixel driving circuit according to an embodiment of the present disclosure.

FIG. 4 is a sectional view of a pixel driving circuit according to an embodiment of the present disclosure.

FIG. 5 is a diagram illustrating a partial structure of the pixel driving circuit in FIG. 3.

FIG. 6 is a diagram illustrating a partial structure of another pixel driving circuit according to an embodiment of the present disclosure.

FIG. 7 is a diagram illustrating a partial structure of another pixel driving circuit according to an embodiment of the present disclosure.

FIG. 8 is a diagram illustrating the formation of an array of the pixel driving circuit in FIG. 3.

FIG. 9 is a diagram illustrating a partial structure of the pixel driving circuit in FIG. 8.

FIG. 10 is a diagram illustrating a partial structure of another pixel driving circuit according to an embodiment of the present disclosure.

FIG. 11 is a diagram illustrating a partial structure of another pixel driving circuit according to an embodiment of the present disclosure.

FIG. 12 is a top view of another pixel driving circuit according to an embodiment of the present disclosure.

FIG. 13 is a diagram illustrating a partial structure of the pixel driving circuit in FIG. 12.

FIG. 14 is a diagram illustrating a partial structure of another pixel driving circuit according to an embodiment of the present disclosure.

FIG. 15 is a top view of another pixel driving circuit according to an embodiment of the present disclosure.

FIG. 16 is a diagram illustrating a partial structure of the pixel driving circuit in FIG. 15.

FIG. 17 is a diagram illustrating a partial structure of another pixel driving circuit according to an embodiment of the present disclosure.

FIG. 18 is a diagram illustrating a partial structure of another pixel driving circuit according to an embodiment of the present disclosure.

FIG. 19 is a diagram illustrating a partial structure of another pixel driving circuit according to an embodiment of the present disclosure.

FIG. 20 is a diagram illustrating a partial structure of another pixel driving circuit according to an embodiment of the present disclosure.

FIG. 21 is a top view of another pixel driving circuit according to an embodiment of the present disclosure.

FIG. 22 is a diagram illustrating a partial structure of the pixel driving circuit in FIG. 3.

FIG. 23 is a diagram illustrating a partial structure of another pixel driving circuit according to an embodiment of the present disclosure.

FIG. 24 is a top view of another array substrate according to an embodiment of the present disclosure.

FIG. 25 is a diagram illustrating a partial structure of the pixel driving circuit in FIG. 3.

FIG. 26 is a diagram illustrating a partial structure of another pixel driving circuit according to an embodiment of the present disclosure.

FIG. 27 is a diagram illustrating a partial structure of another pixel driving circuit according to an embodiment of the present disclosure.

FIG. 28 is a diagram illustrating a partial structure of another pixel driving circuit according to an embodiment of the present disclosure.

FIG. 29 is a sectional view of a display panel according to an embodiment of the present disclosure.

FIG. 30 is a diagram of a display apparatus according to an embodiment of the present disclosure.

### DETAILED DESCRIPTION

Hereinafter the present disclosure is further described in detail in conjunction with

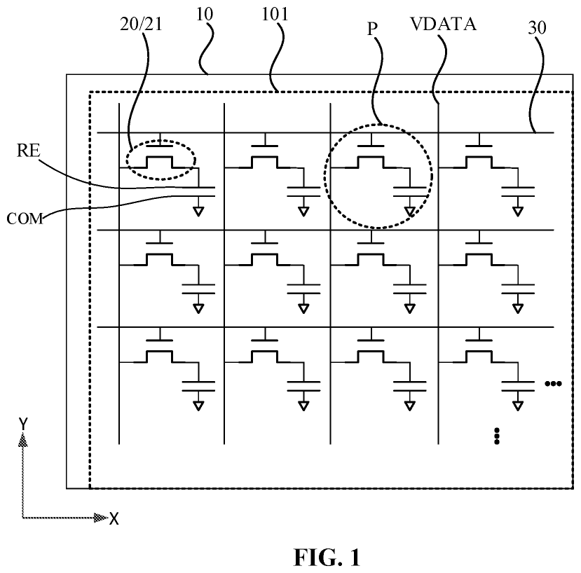

the drawings and embodiments. It is to be understood that the embodiments described herein are intended to illustrate and not to limit the present disclosure. Additionally, it is to be noted that for ease of description, only part, not all, of structures related to the present disclosure are illustrated in the drawings. FIG. 1 is a top view of an array substrate according to an embodiment of the present

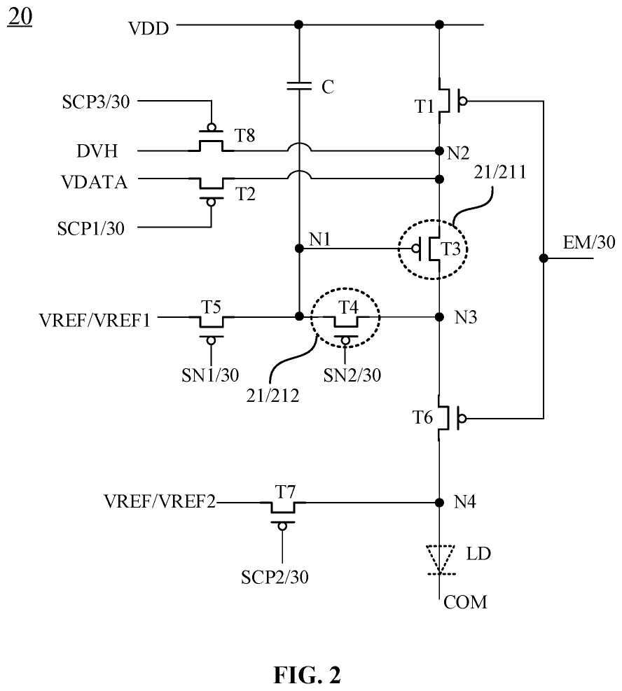

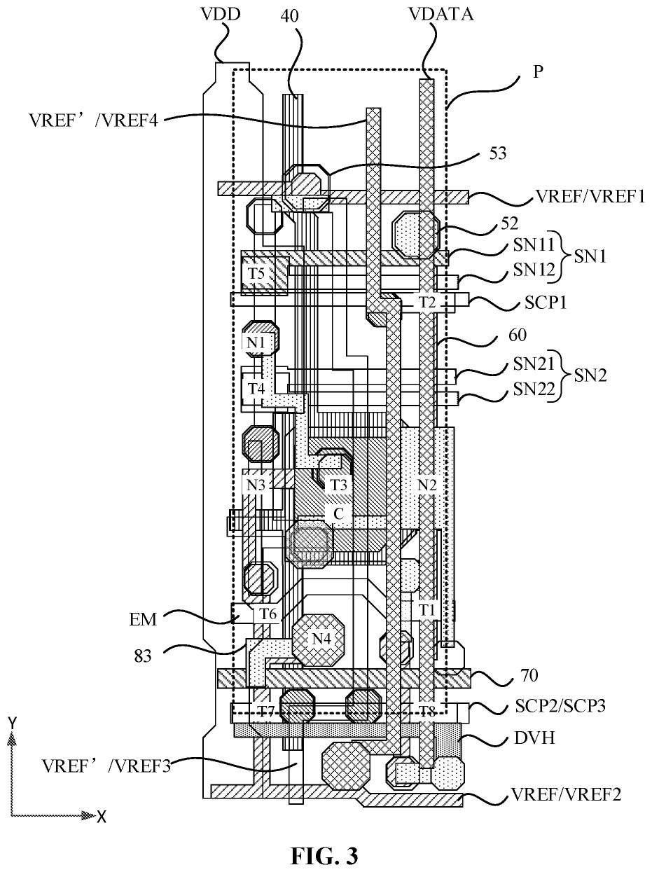

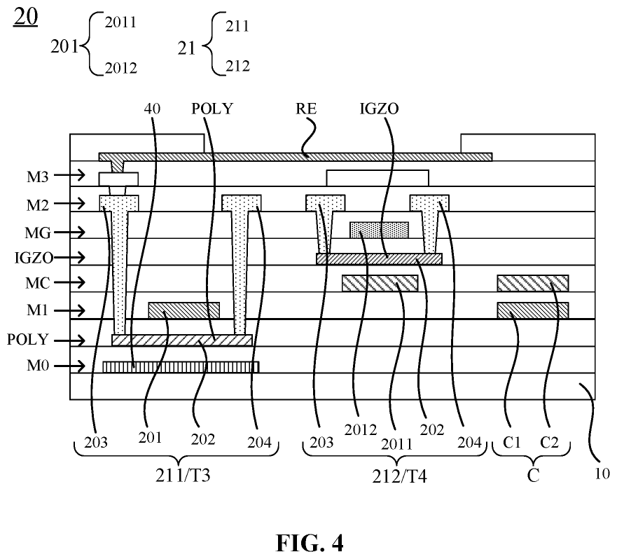

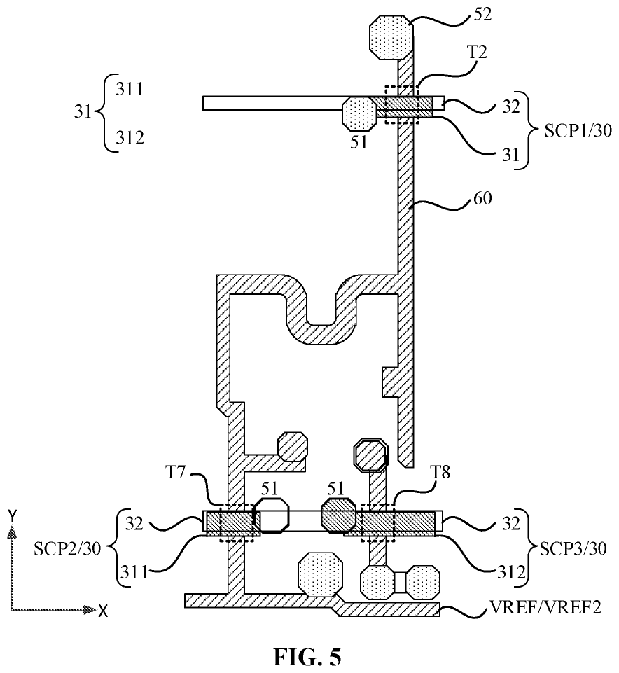

disclosure. FIG. 2 is a diagram illustrating a circuit structure of a pixel driving circuit according to an embodiment of the present disclosure. FIG. 3 is a top view of a pixel driving circuit according to an embodiment of the present disclosure. FIG. 4 is a sectional view of a pixel driving circuit according to an embodiment of the present disclosure. FIG. 5 is a diagram illustrating a partial structure of the pixel driving circuit in FIG. 3. Referring to FIGS. 1 to 5, the array substrate includes a display region 101 including a plurality of pixel regions P. In the display region 101, the pixel areas P are arranged in rows in a first direction X and a second direction Y. The arrangement of pixel regions P is not limited in the present disclosure.

The array substrate includes a substrate 10, pixel driving circuits 20, and gate control signal lines 30. The gate control signal lines 30 are configured to supply scanning signals to the pixel driving circuits 20 and are used for controlling thin-film transistors of the pixel driving circuits 20 to turn on or off.

In the related art, the gate control signal lines 30 are scanning signal lines 31. The resistance of a layer where the scanning signal lines 31 are located is relatively great.

In the present disclosure, the gate control signal lines 30 include scanning signal lines 31 and auxiliary signal lines 32. At least part of a pixel driving circuit 20 and at least part of a scanning signal line 31 are located in the display region 101. The scanning signal line 31 may be located in the display region 101. Alternatively, the scanning signal line 31 may extend out of the display region 101 from the inside of the display region 101. The pixel driving circuit 20 and the scanning signal line 31 are located on the same side of the substrate 10. The scanning signal line 31 extends in the first direction X. At least part of the pixel driving circuit 20 is located in a pixel region P and includes thin-film transistors 21. A thin-film transistor 21 includes a gate 201 and a channel layer 202. The gate 201 is a portion where the scanning signal line 31 overlaps the channel layer 202. An auxiliary signal line 32 is located in the display region 101 and extends in the first direction X. The resistance of the auxiliary signal line 32 is smaller than the resistance of the scanning signal line 31. The auxiliary signal line 32 and the scanning signal line 31 are disposed in different layers. The auxiliary signal line 32 is electrically connected to the scanning signal line 31 through a line exchanging through hole 51.

For the array substrate according to an embodiment of the present disclosure, the gate control signal lines 30 include the scanning signal lines 31 and the auxiliary signal lines 32. The auxiliary signal lines 32 are provided for the scanning signal lines 31. The resistance of the auxiliary signal line 32 is smaller than the resistance of the scanning signal line 31. The auxiliary signal line 32 is electrically connected to the scanning signal line 31 through the line exchanging through hole 51. Therefore, when a scanning signal is transmitted, the scanning signal can be transmitted both on the scanning signal line 31 with a relatively great resistance and on the auxiliary signal line 32 with a relatively small resistance, reducing the resistance of a gate control signal line 30, reducing the transmission voltage drop of the scanning signal, and improving the display performance.

Illustratively, referring to FIG. 2, the pixel driving circuit 20 includes a power write transistor T1, a data write transistor T2, a drive transistor T3, a compensation transistor T4, a first reset transistor T5, a light emission control transistor T6, a second reset transistor T7, an adjustment transistor T8, and a storage capacitor C. A first electrode of the power write transistor T1 is electrically connected to a first power line VDD. A second electrode of the power write transistor T1 is electrically connected to a second node N2. A gate of the power write transistor T1 is electrically connected to a light emission control signal line EM. A first electrode of the data write transistor T2 is electrically connected to a data line VDATA. A second electrode of the data write transistor T2 is electrically connected to the second node N2. A gate of the data write transistor T2 is electrically connected to a data control signal line SCP1. A first electrode of the drive transistor T3 is electrically connected to the second node N2. A second electrode of the drive transistor T3 is electrically connected to a third node N3. A gate of the drive transistor T3 is electrically connected to a first node N1. A first electrode of the compensation transistor T4 is electrically connected to the first node N1. A second electrode of the compensation transistor T4 is electrically connected to the third node N3. A gate of the compensation transistor T4 is electrically connected to a second scanning line SN2. A first electrode of the first reset transistor T5 is electrically connected to a first reset signal transmission line VREF1. A second electrode of the first reset transistor T5 is electrically connected to the first node N1. A gate of the first reset transistor T5 is electrically connected to a first scanning line SN1. A first electrode of the light emission control transistor T6 is electrically connected to the third node N3. A second electrode of the light emission control transistor T6 is electrically connected to a fourth node N4. A gate of the light emission control transistor T6 is electrically connected to the light emission control signal line EM. A first electrode of the second reset transistor T7 is electrically connected to a second reset signal transmission line VREF2. A second electrode of the second reset transistor T7 is electrically connected to the fourth node N4. A gate of the second reset transistor T7 is electrically connected to an anode reset control signal line SCP2. A first electrode of the adjustment transistor T8 is electrically connected to an adjustment signal transmission line DVH. A second electrode of the adjustment transistor T8 is electrically connected to the second node N2. A gate of the adjustment transistor T8 is electrically connected to an adjustment control signal line SCP3. A first plate C1 of the storage capacitor C is electrically connected to the first node N1. A second plate C2 of the storage capacitor C is electrically connected to the first power line VDD.

The first node N1, the second node N2, the third node N3, and the fourth node N4 may be virtually existing connection nodes or may be actually existing connection nodes.

It is to be noted that the circuit diagram shown in FIG. 2 is only an example and is not a limitation of the present disclosure. In other embodiments, the pixel driving circuit 20 with another circuit structure may also be provided.

Illustratively, referring to FIG. 2, the gate control signal lines 30 include the scanning signal lines 31. The scanning signal lines 31 include the light emission control signal line EM, first scanning lines SN1, second scanning lines SN2, the data control signal line SCP1, the anode reset control signal line SCP2, and the adjustment control signal line SCP3.

Illustratively, referring to FIG. 4, the array substrate includes a silicon semiconductor layer POLY, a first metal layer M1, a first sub-gate metal layer MC, an oxide semiconductor layer IGZO, a second sub-gate metal layer MG, a second metal layer M2, and a third metal layer M3 that are stacked. The silicon semiconductor layer POLY is disposed between the substrate 10 and the first metal layer M1. The silicon semiconductor layer POLY includes silicon. The oxide semiconductor layer IGZO includes an oxide semiconductor material.

Multiple thin-film transistors 21 include silicon transistors 211 and oxide transistors 212. A silicon transistor 211 includes a gate 201, a channel layer 202, a source 203, and a drain 204. The gate 201 of the silicon transistor 211 is located in the first metal layer M1. The channel layer 202 of the silicon transistor 211 is located in the silicon semiconductor layer POLY. The source 203 of the silicon transistor 211 and the drain 204 of the silicon transistor 211 are each located in the second metal layer M2. A scanning signal line 31 electrically connected to the gate 201 of the silicon transistor 211 is located in the first metal layer M1. An oxide transistor 212 includes gates 201, a channel layer 202, a source 203, and a drain 204. The gates 201 of the oxide transistor 212 include a first sub-gate 2011 and a second sub-gate 2012. In a direction perpendicular to the substrate 10, the first sub-gate 2011 is disposed between the channel layer 202 and the substrate 10, and the second sub-gate 2012 is disposed on one side of the channel layer 202 facing away from the substrate 10. The channel layer 202 of the oxide transistor 212 is located in the oxide semiconductor layer IGZO. The source 203 of the oxide transistor 212 and the drain 204 of the oxide transistor 212 are each located in the second metal layer M2. A scanning signal line 31 electrically connected to the gates 201 of the oxide transistor 212 is located in the first sub-gate metal layer MC or the second sub-gate metal layer MG.

Illustratively, referring to FIGS. 2 and 4, the power write transistor T1, the data write transistor T2, the drive transistor T3, the light emission control transistor T6, the second reset transistor T7, and the adjustment transistor T8 are each a silicon transistor 211. The compensation transistor T4 and the first reset transistor T5 are each an oxide transistor 212. Since the compensation transistor T4 and the first reset transistor T5 are each connected to the first node N1, the compensation transistor T4 and the first reset transistor T5 are each configured to be an oxide transistor 212 so as to reduce the leakage current to the first node N1

Illustratively, referring to FIGS. 2 to 4, the first scanning lines SN1 include a first scanning sub-line SN11 and a second scanning sub-line SN12. The second scanning lines SN2 include a third scan sub-line SN21 and a fourth scan sub-line SN22. The data control signal line SCP1, the light emission control signal line EM, the anode reset control signal line SCP2, and the adjustment control signal line SCP3 are each located in the first metal layer M1. The first scanning sub-line SN11 and the third scan sub-line SN21 are each located in the first sub-gate metal layer MC. The second scanning sub-line SN12 and the fourth scan sub-line SN22 are each located in the second sub-gate metal layer MG.

Optionally, referring to FIGS. 3 to 5, a layer where the auxiliary signal line 32 is located is disposed on one side of a layer where the scanning signal line 31 is located facing away from the substrate 10. The auxiliary signal line 32 may be produced by using an original metal layer on a side of the second sub-gate metal layer MG facing away from the substrate 10 so that no newly-added metal layer needs to be provided.

Optionally, referring to FIGS. 3 to 5, a thin-film transistor 21 includes a source 203 and a drain 204. The auxiliary signal line 32, the source 203, and the drain 204 are in the same layer. Therefore, the auxiliary signal line 32, the source 203, and the drain 204 are formed by using the same material in the same process, thereby saving the process. The auxiliary signal line 32 is located in the second metal layer M2. The resistance of the second metal layer M2 is relatively small, reducing the transmission voltage drop of the scanning signal.

Optionally, referring to FIGS. 3 to 5, in the first direction, the length of the scanning signal line 31 is smaller than the length of the auxiliary signal line 32. The resistance of the scanning signal line 31 is relatively great. The resistance of the auxiliary signal line 32 is relatively small. Therefore, the auxiliary signal line 32 with a relatively small resistance is provided with a relatively great length, and the scanning signal line 31 with a relatively great resistance is provided with a relatively small length, which is conducive to the reduction of the resistance of a gate control signal line 30 formed by the electrical connection of the scanning signal line 31 and the auxiliary signal line 32 and the reduction of the transmission voltage drop of the scanning signal.

Optionally, referring to FIGS. 3 to 5, in the direction perpendicular to the substrate 10, the scanning signal line 31 overlaps the auxiliary signal line 32 in a region other than a region where the line exchanging through hole 51 is located. In the direction perpendicular to the substrate 10, the scanning signal line 31 overlaps the auxiliary signal line 32, and the scanning signal line 31 and the auxiliary signal line 32 each overlap the line exchanging through hole 51. Therefore, a light-shielding region of the scanning signal line 31 overlaps a light-shielding region of the auxiliary signal line 32, reducing a common light-shielding area of the scanning signal line 31 and the auxiliary signal line 32 and increasing transmittance.

Illustratively, referring to FIGS. 3 to 5, in a region where a thin-film transistor 21 (for example, the second reset transistor T7 and the adjustment transistor T8 in FIG. 5) is located, the scanning signal line 31 overlaps the auxiliary signal line 32 in the direction perpendicular to the substrate 10. If the scanning signal line 31 and the auxiliary signal line 32 are misaligned in the region where the thin-film transistor 21 is located, a ramp would be formed at an edge of the scanning signal line 31 after the scanning signal line 31 is formed (it is to be understood that the layer thickness of the position where the scanning signal line 31 is formed is greater than the layer thickness of the position where no scanning signal line 31 is formed). When the auxiliary signal line 32 is formed, the second metal layer M2 where the auxiliary signal line 32 is located is caused to be not flat. Therefore, the scanning signal line 31 overlaps the auxiliary signal line 32 so as to increase the flatness of the second metal layer M2 where the auxiliary signal line 32 is located.

Optionally, referring to FIGS. 1, 3, and 5, a plurality of collinear scanning signal lines 31 are electrically connected to the same auxiliary signal line 32. The collinear scanning signal lines 31 are arranged in the first direction X and are electrically connected to the same auxiliary signal line 32 through line exchanging through holes 51. The auxiliary signal line 32 is an entire straight line segment. The length of the auxiliary signal line 32 is relatively great. The auxiliary signal line 32 with a relatively small resistance is provided with a relatively great length, reducing the transmission voltage drop of the scanning signal.

Illustratively, a plurality of scanning signal lines 31 and one auxiliary signal line 32 are collinear in the first direction X.

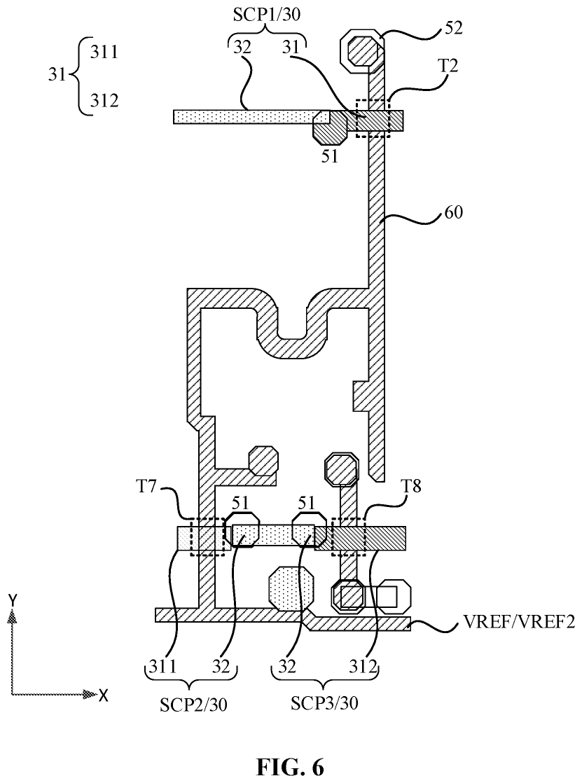

FIG. 6 is a diagram illustrating a partial structure of another pixel driving circuit according to an embodiment of the present disclosure. Referring to FIG. 6, an end of a scanning signal line 31 is electrically connected to an end of an auxiliary signal line 32. In the first direction X, scanning signal lines 31 and auxiliary signal lines 32 are arranged alternately. One auxiliary signal line 32 is disposed between two adjacent scanning signal lines 31. The two adjacent scanning signal lines 31 are electrically connected to each other through the auxiliary signal line 32 between the two adjacent scanning signal lines 31.

Illustratively, a plurality of scanning signal lines 31 and a plurality of auxiliary signal lines 32 are collinear in the first direction X. One scanning signal line 31 is disposed between two adjacent auxiliary signal lines 32.

Optionally, still referring to FIGS. 3 and 5, the collinear scanning signal lines 31 include a first scanning signal line 311 and a second scanning signal line 312 which are disposed at intervals from each other. The first scanning signal line 311 and the second scanning signal line 312 are located in the same pixel region P. In this embodiment of the present disclosure, two collinear scanning signal lines 31 are disposed at intervals from each other in the same pixel region P. The two collinear scanning signal lines 31 are disposed discretely, independently, and in a disconnected manner.

Optionally, still referring to FIGS. 2, 3, and 5, the thin-film transistors 21 include the drive transistor T3 used for supplying a drive current to a light-emitting element LD. The first scanning signal line 311 is configured to control a thin-film transistor 21 (specifically, the second reset transistor T7) to transmit a reset signal to an anode of the light-emitting element LD. The second scanning signal line 312 is configured to control a thin-film transistor 21 (specifically, the adjustment transistor T8) to transmit an adjustment signal to the first electrode of the drive transistor T3. In this embodiment of the present disclosure, the first scanning signal line 311 includes the anode reset control signal line SCP2. The second scanning signal line 312 includes the adjustment control signal line SCP3. The first scanning signal line 311 and the second scanning signal line 312 are collinear and are electrically connected to the same auxiliary signal line 32. Therefore, the anode reset control signal line SCP2 also serves as the adjustment control signal line SCP3. The second reset transistor T7 and the adjustment transistor T8 share the same gate control signal line 30.

Illustratively, as shown in FIGS. 3 to 5, the first scanning signal line 311 includes the anode reset control signal line SCP2. The gate of the second reset transistor T7 is formed in the position where the anode reset control signal line SCP2 overlaps a channel layer 202. The second scanning signal line 312 includes the adjustment control signal line SCP3. The gate of the adjustment transistor T8 is formed in the position where the adjustment control signal line SCP3 overlaps a channel layer 202. The gate of the second reset transistor T7 and the gate of the adjustment transistor T8 are disposed in the same layer. The gate of the second reset transistor T7 and the gate of the adjustment transistor T8 are collinear. Moreover, the gate of the second reset transistor T7 is disconnected from the gate of the adjustment transistor T8. That is, the gate of the second reset transistor T7 and the gate of the adjustment transistor T8 are not connected together through a metal in the same layer.

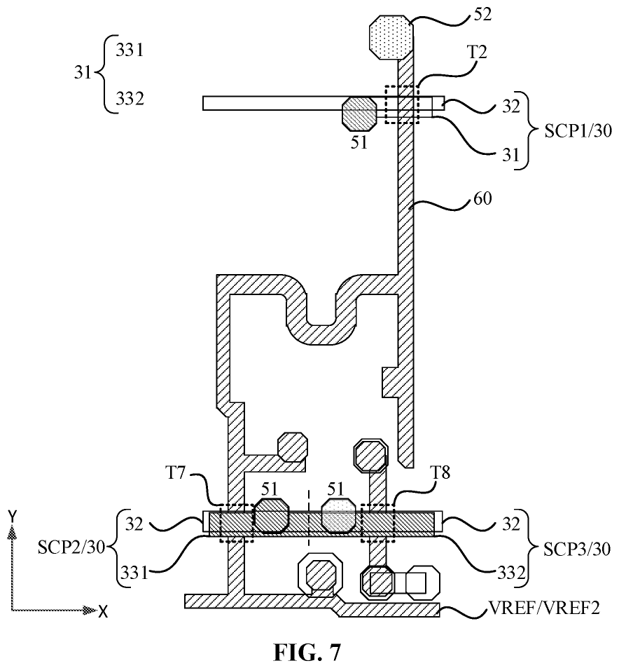

FIG. 7 is a diagram illustrating a partial structure of another pixel driving circuit according to an embodiment of the present disclosure. Referring to FIGS. 4 and 7, a scanning signal line 31 includes a first signal line segment 331 and a second signal line segment 332 that are connected to each other. The first signal line segment 331 and the second signal line segment 332 are located in the same pixel region P. The first signal line segment 331 and the second signal line segment 332 each include a gate 201. In this embodiment of the present disclosure, in the same pixel region P, the first signal line segment 331 and the second signal line segment 332 are different portions of the same scanning signal line 31. The same scanning signal line 31 overlaps at least two channel layers 202 to form at least two gates 201.

Illustratively, as shown in FIGS. 3, 4, and 7, the scanning signal line 31 includes the first signal line segment 331 and the second signal line segment 332. The first signal line segment 331 and the second signal line segment 332 are different portions of the same scanning signal line 31. The first signal line segment 331 includes the anode reset control signal line SCP2. The gate of the second reset transistor T7 is formed in the position where the anode reset control signal line SCP2 overlaps a channel layer 202. The second signal line segment 332 includes the adjustment control signal line SCP3. The gate of the adjustment transistor T8 is formed in the position where the adjustment control signal line SCP3 overlaps a channel layer 202. The gate of the second reset transistor T7 and the gate of the adjustment transistor T8 are in the same layer. The gate of the second reset transistor T7 is connected to the gate of the adjustment transistor T8. That is, the gate of the second reset transistor T7 and the gate of the adjustment transistor T8 are connected together through a metal in the same layer.

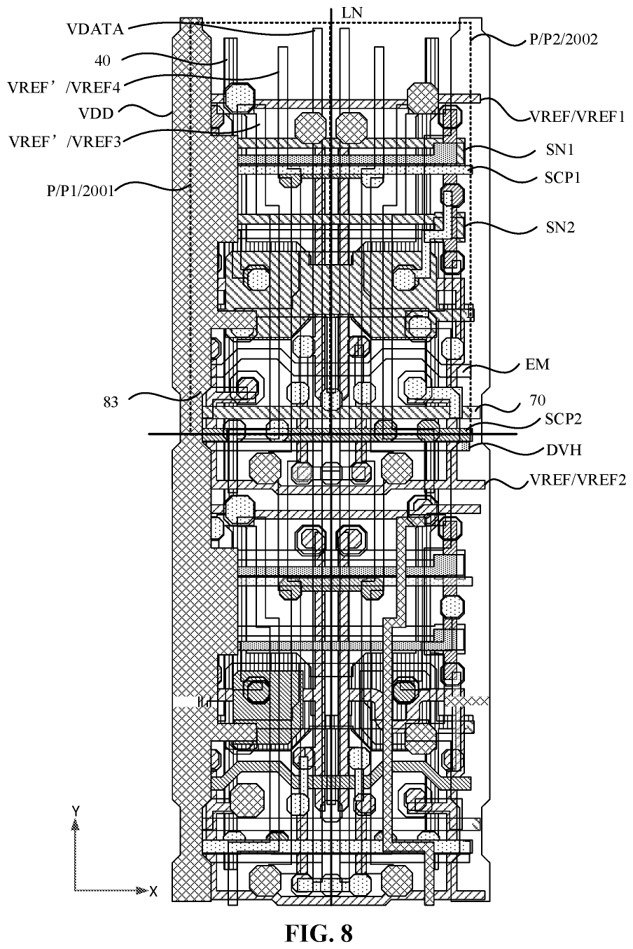

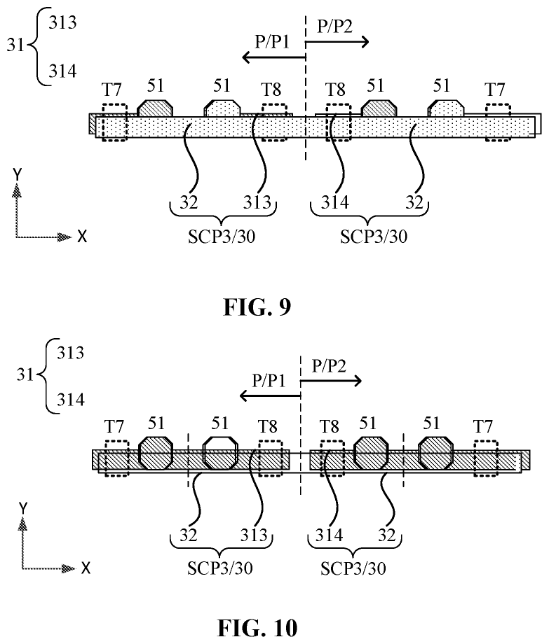

FIG. 8 is a diagram illustrating the formation of an array of the pixel driving circuit in FIG. 3. FIG. 9 is a diagram illustrating a partial structure of the pixel driving circuit in FIG. 8. Referring to FIGS. 8 and 9, the pixel regions P include a first pixel region Pl and a second pixel region P2 that are disposed adjacent to each other in the first direction X. The collinear scanning signal lines 31 include a third scanning signal line 313 and a fourth scanning signal line 314 which are disposed at intervals from each other. The third scanning signal line 313 is located in the first pixel region P1. The fourth scanning signal line 314 is located in the second pixel region P2. In this embodiment of the present disclosure, the third scanning signal line 313 in the first pixel region P1 and the fourth scanning signal line 314 in the second pixel region P2 are collinear. The third scanning signal line 313 in the first pixel region P1 and the fourth scanning signal line 314 in the second pixel region P2 are spaced apart. Collinear scanning signal lines 31 in adjacent pixel regions P are disposed discretely, independently, and in a disconnected manner.

Illustratively, referring to FIGS. 8 and 9, the third scanning signal line 313 and the fourth scanning signal line 314 both include the adjustment control signal line SCP3. A gate of an adjustment transistor T8 is formed in the position where the adjustment control signal line SCP3 overlaps a channel layer 202. A gate of an adjustment transistor T8 in the first pixel region P1 is disconnected from a gate of an adjustment transistor T8 in the second pixel region P2.

Illustratively, referring to FIG. 9, in the first pixel region P1, a gate of a second reset transistor T7 is disconnected from the gate of the adjustment transistor T8. In the second pixel region P2, a gate of a second reset transistor T7 is disconnected from the gate of the adjustment transistor T8. The gate of the adjustment transistor T8 in the first pixel region P1 is disconnected from the gate of the adjustment transistor T8 in the second pixel region P2.

FIG. 10 is a diagram illustrating a partial structure of another pixel driving circuit according to an embodiment of the present disclosure. Referring to FIG. 10, in the first pixel region P1, the gate of the second reset transistor T7 is connected to the gate of the adjustment transistor T8. In the second pixel region P2, the gate of the second reset transistor T7 is connected to the gate of the adjustment transistor T8. The gate of the adjustment transistor T8 in the first pixel region PI is disconnected from the gate of the adjustment transistor T8 in the second pixel region P2.

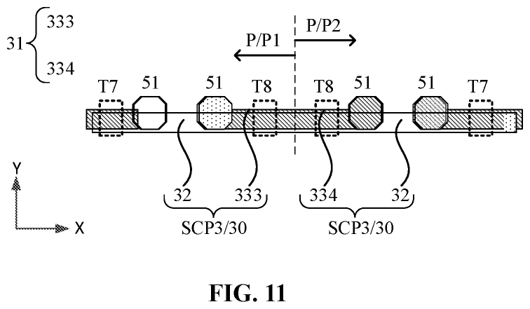

FIG. 11 is a diagram illustrating a partial structure of another pixel driving circuit according to an embodiment of the present disclosure. Referring to FIG. 11, the pixel regions P include the first pixel region P1 and the second pixel region P2 that are disposed adjacent to each other in the first direction X. A scanning signal line 31 includes a third signal line segment 333 and a fourth signal line segment 334 that are connected to each other. The third signal line segment 333 is located in the first pixel region P1 and includes a gate 201. The fourth signal line segment 334 is located in the second pixel region P2 and includes a gate 201. In this embodiment of the present disclosure, the third signal line segment 333 and the fourth signal line segment 334 are different portions of the same scanning signal line 31. The scanning signal line 31 is located in the first pixel region P1 and the second pixel region P2 and overlaps at least two channel layers 202 in the first pixel region P1 and the second pixel region P2 to form at least two gates 201.

Illustratively, referring to FIG. 11, the scanning signal line 31 includes the third signal line segment 333 and the fourth signal line segment 334 that are connected to each other. The third signal line segment 333 includes the adjustment control signal line SCP3. The gate 201 of the adjustment transistor T8 in the first pixel region P1 is formed in the position where the third signal line segment 333 overlaps a channel layer 202 in the first pixel region P1. The fourth signal line segment 334 includes the adjustment control signal line SCP3. The gate 201 of the adjustment transistor T8 in the second pixel region P2 is formed in the position where the third signal line segment 333 overlaps a channel layer 202 in the second pixel region P2. The gate 201 of the adjustment transistor T8 in the first pixel region P1 is connected to the gate 201 of the adjustment transistor T8 in the second pixel region P2.

It is to be further noted that if the gate 201 of the adjustment transistor T8 in the first pixel region P1 is disconnected from the gate 201 of the adjustment transistor T8 in the second pixel region P2, the channel layer 202 in the first pixel region Pl and the channel layer 202 in the second pixel region P2 would have a relatively small distance. The scanning signal line 31 formed on the silicon semiconductor layer POLY (specifically, channel layers 202) needs to totally overlap the channel layers 202. That is, an edge of the scanning signal line 31 cannot overlap the silicon semiconductor layer POLY but needs to extend a certain distance beyond the channel layers 202 in the first direction X. Such a margin design helps avoid an offset of the scanning signal line 31 relative to the channel layers 202 due to a process fluctuation. If the gate 201 of the adjustment transistor T8 in the first pixel region P1 is connected to the gate 201 of the adjustment transistor T8 in the second pixel region P2, no certain space needs to be reserved for a process fluctuation, reducing process difficulty, reducing the space occupied by a single pixel region P, and thereby improving pixel density.

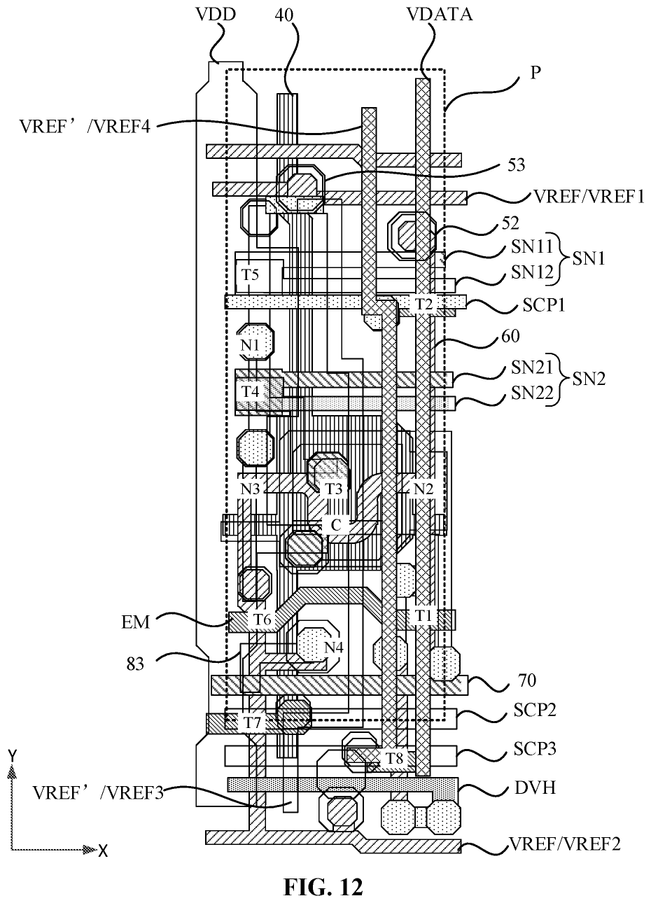

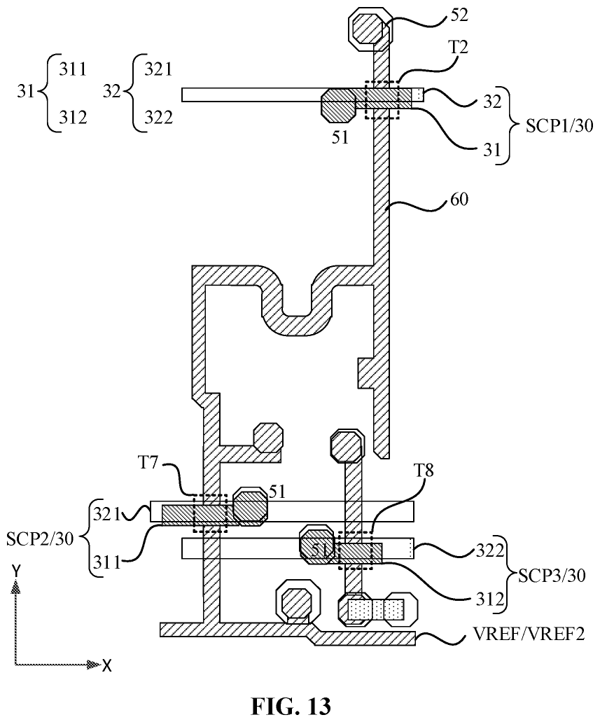

FIG. 12 is a top view of another pixel driving circuit according to an embodiment of the present disclosure. FIG. 13 is a diagram illustrating a partial structure of the pixel driving circuit in FIG. 12. Referring to FIGS. 12 and 13, a plurality of auxiliary signal lines 32 include a first auxiliary signal line 321 and a second auxiliary signal line 322 that are arranged in the second direction Y. The second direction Y intersects the first direction X. The thin-film transistors 21 include the drive transistor T3 used for supplying the drive current to the light-emitting element LD. A plurality of scanning signal lines 31 include the first scanning signal line 311 and the second scanning signal line 312. The first scanning signal line 311 is configured to control a thin-film transistor 21 (specifically, the second reset transistor T7) to transmit a reset signal to the anode of the light-emitting element LD. The second scanning signal line 312 is configured to control a thin-film transistor 21 (specifically, the adjustment transistor T8) to transmit an adjustment signal to the first electrode of the drive transistor T3. The first scanning signal line 311 is electrically connected to the first auxiliary signal line 321. The second scanning signal line 312 is electrically connected to the second auxiliary signal line 322. In this embodiment of the present disclosure, the first scanning signal line 311 and the second scanning signal line 312 are not collinear. The first scanning signal line 311 and the second scanning signal line 312 are arranged in the second direction Y. Therefore, the second reset transistor T7 and the adjustment transistor T8 are connected to two different gate control signal lines 30.

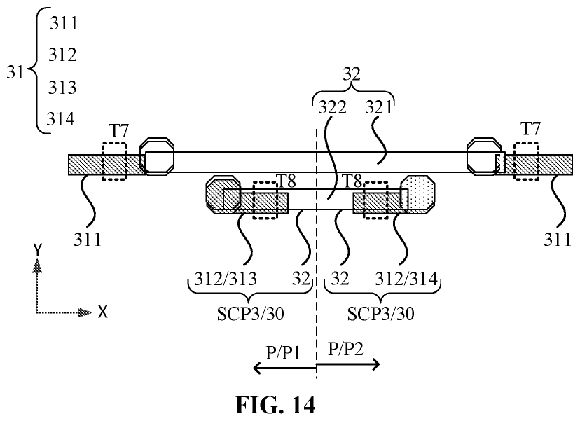

FIG. 14 is a diagram illustrating a partial structure of another pixel driving circuit according to an embodiment of the present disclosure. Referring to FIG. 14, an end of a scanning signal line 31 is electrically connected to an end of an auxiliary signal line 32. The gate of the second reset transistor T7 in the first pixel region P1 is disconnected from the gate of the second reset transistor T7 in the second pixel region P2. An end of a first scanning signal line 311 in the first pixel region P1 is electrically connected to a first end of the first auxiliary signal line 321. An end of a first scanning signal line 311 in the second pixel region P2 is electrically connected to a second end of the first auxiliary signal line 321. The gate of the adjustment transistor T8 in the first pixel region P1 is disconnected from the gate of the adjustment transistor T8 in the second pixel region P2. An end of a second scanning signal line 312 in the first pixel region P1 is electrically connected to a first end of the second auxiliary signal line 322. An end of a second scanning signal line 312 in the second pixel region P2 is electrically connected to a second end of the second auxiliary signal line 322.

Optionally, referring to FIGS. 3 to 5, the pixel driving circuit 20 further includes the storage capacitor C. A vertical projection of an auxiliary signal line 32 on the substrate 10 and a vertical projection of the storage capacitor C on the substrate 10 are arranged in the second direction Y. The second direction Y intersects the first direction X. In the second direction Y, the auxiliary signal line 32 is located on one side of the storage capacitor C. In the direction perpendicular to the substrate 10, the auxiliary signal line 32 does not overlap the storage capacitor C. The auxiliary signal line 32 in this embodiment of the present disclosure is a line extending in the first direction X and is not a light-shielding metal layer. A light-shielding metal layer generally does not avoid the storage capacitor C. The auxiliary signal line 32 in this embodiment of the present disclosure is misaligned with the storage capacitor C and does not aim at shielding light. On the contrary, the design aims to increase transmittance and reduce the transmission voltage drop of the scanning signal. Multiple auxiliary signal lines 32 arranged in the second direction Y may be disposed in one pixel region P to reduce the transmission voltage drop of transmitting scanning signals on multiple scanning signal lines 31.

Optionally, referring to FIGS. 3, 5, 12, and 13, a plurality of scanning signal lines 31 include the anode reset control signal line SCP2 and the adjustment control signal line SCP3. In the second direction Y, the anode reset control signal line SCP2 and the adjustment control signal line SCP3 are located on the same side of the storage capacitor C. An auxiliary signal line 32 electrically connected to the anode reset control signal line SCP2 is a straight line segment. An auxiliary signal line 32 electrically connected to the adjustment control signal line SCP3 is a straight line segment. Compared with a bend line segment or a curve line segment, a straight line segment is simple in structure and is not easily affected by over-etching, reducing process difficulty.

Illustratively, referring to FIGS. 3, 5, 12, and 13, the anode reset control signal line SCP2 and the adjustment control signal line SCP3 are each located between the fourth node N4 and the adjustment signal transmission line DVH. No other line or hole of the second metal layer M2 exists between the fourth node N4 and the adjustment signal transmission line DVH. Therefore, the auxiliary signal line 32 electrically connected to the anode reset control signal line SCP2 and the auxiliary signal line 32 electrically connected to the adjustment control signal line SCP3 do not need to be bent or curved for avoidance.

Illustratively, referring to FIGS. 12 and 13, the first auxiliary signal line 321 and the second auxiliary signal line 322 are each a straight line segment.

Optionally, referring to FIGS. 3, 5, 12, and 13, the scanning signal lines 31 include the data control signal line SCP1. The data control signal line SCP1 is configured to control a thin-film transistor (specifically, the data write transistor T2) to transmit a data signal to the first electrode of the drive transistor T3. The array substrate further includes the data line VDATA and a data line through hole 52. The data line VDATA is connected through the data line through hole 52 to a semiconductor wire 60 that is disposed in a different layer from the data line VDATA. A channel layer 202 is a portion where the semiconductor wire 60 overlaps a gate 201. A portion where the semiconductor wire 60 does not overlap the gate 201 serves as a connection line. The conductivity of the portion where the semiconductor wire 60 does not overlap the gate 201 is usually improved by doping. In the second direction Y, the data control signal line SCP1 is disposed on one side of the storage capacitor C facing away from the anode reset control signal line SCP2. At least one scanning signal line 31 is disposed between the data control signal line SCP1 and the data line through hole 52. The data control signal line SCP1 is relatively far from the data line through hole 52, thereby not needing to be bent or curved for avoiding the data line through hole 52. An auxiliary signal line 32 electrically connected to the data control signal line SCP1 is a straight line segment. Illustratively, referring to FIGS. 3, 5, 12, and 13, a first scanning line SN1 is disposed

between the data control signal line SCP1 and the data line through hole 52. The data control signal line SCP1 is relatively far from the data line through hole 52.

Optionally, referring to FIGS. 3 and 12, the array substrate further includes the adjustment signal transmission line DVH used for transmitting an adjustment signal. The adjustment signal transmission line DVH extends in the first direction X. A layer where the adjustment signal transmission line DVH is located is disposed between a layer where the adjustment control signal line SCP3 is located and a layer where an auxiliary signal line 32 is located. A vertical projection of the adjustment control signal line SCP3 on the substrate 10 is misaligned with a vertical projection of the adjustment signal transmission line DVH on the substrate 10. In the direction perpendicular to the substrate 10, the adjustment control signal line SCP3 does not overlap the adjustment signal transmission line DVH. Therefore, the adjustment signal transmission line DVH located between the layer where the adjustment control signal line SCP3 is located and the layer where the auxiliary signal line 32 is located does not overlap a line exchanging through hole 51 through which the adjustment control signal line SCP3 is connected to the auxiliary signal line 32, avoiding an undesired electrical connection of the adjustment signal transmission line DVH and the adjustment control signal line SCP3.

Illustratively, referring to FIGS. 3, 4, and 12, the adjustment signal transmission line DVH is located in the second sub-gate metal layer MG. The adjustment control signal line SCP3 is located in the first metal layer M1. The auxiliary signal line 32 is located in the second metal layer M2. The second sub-gate metal layer MG is disposed between the first metal layer M1 and the second metal layer M2. If the adjustment signal transmission line DVH is configured to overlap the adjustment control signal line SCP3, the adjustment signal transmission line DVH would be connected to the line exchanging through hole 51 connecting the second metal layer M2 and the first metal layer M1. In such way, the adjustment signal transmission line DVH is electrically connected to the adjustment control signal line SCP3, and the pixel driving circuit 20 fails to work normally.

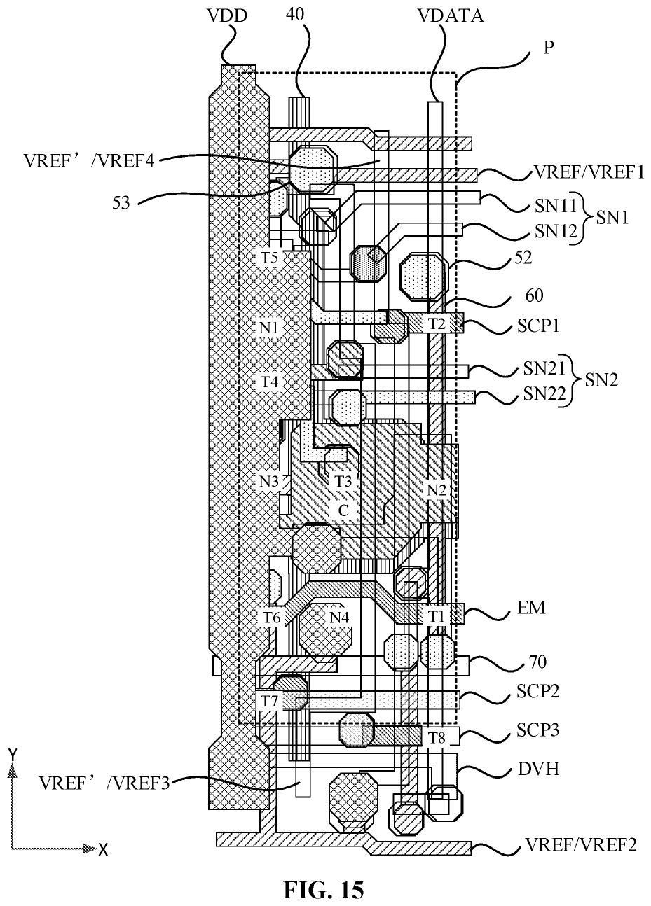

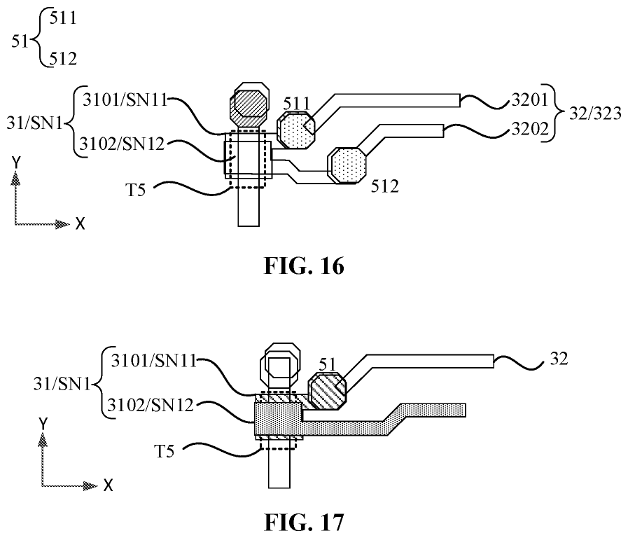

FIG. 15 is a top view of another pixel driving circuit according to an embodiment of the present disclosure. FIG. 16 is a diagram illustrating a partial structure of the pixel driving circuit in FIG. 15. Referring to FIGS. 4, 15, and 16, the scanning signal lines 31 include a first signal sub-line 3101 and a second signal sub-line 3102. Gates 201 include a first sub-gate 2011 and a second sub-gate 2012. In the direction perpendicular to the substrate 10, the first sub-gate 2011 is disposed between a channel layer 202 (specifically, the channel layer 202 in the oxide semiconductor layer IGZO) and the substrate 10. The second sub-gate 2012 is disposed on one side of the channel layer 202 (specifically, the channel layer 202 in the oxide semiconductor layer IGZO) facing away from the substrate 10. The first sub-gate 2011 is a portion where the first signal sub-line 3101 overlaps the channel layer 202. The second sub-gate 2012 is a portion where the second signal sub-line 3102 overlaps the channel layer 202. The first signal sub-line 3101 and/or the second signal sub-line 3102 is electrically connected to an auxiliary signal line 32 through a line exchanging through hole 51.

Illustratively, referring to FIGS. 15 and 16, the scanning signal lines 31 include the first scanning lines SN1. The first scanning lines SN1 include the first scanning sub-line SN11 and the second scanning sub-line SN12. The first scanning sub-line SN11 is the first signal sub-line 3101. The second scanning sub-line SN12 is the second signal sub-line 3102. The first scanning sub-line SN11 and the second scanning sub-line SN12 are electrically connected to two auxiliary signal lines 32 through two line exchanging through holes 51 separately.

It is to be understood that a scanning signal line 31 connected to a gate of a silicon transistor 211 is configured to be electrically connected to an auxiliary signal line 32, reducing the voltage drop of a scanning signal transmitted on the scanning signal line 31 connected to the gate of the silicon transistor 211. A scanning signal line 31 connected to a gate of an oxide transistor 212 is configured to be electrically connected to an auxiliary signal line 32, reducing the voltage drop of a scanning signal transmitted on the scanning signal line 31 connected to the gate of the oxide transistor 212. Therefore, a difference between the voltage drop of the scanning signal of the silicon transistor 211 and the voltage drop of the scanning signal of the oxide transistor 212 is reduced.

FIG. 17 is a diagram illustrating a partial structure of another pixel driving circuit according to an embodiment of the present disclosure. Referring to FIG. 17, the first scanning sub-line SN11 is the first signal sub-line 3101. The second scanning sub-line SN12 is the second signal sub-line 3102. The first scanning sub-line SN11 is electrically connected to an auxiliary signal line 32 through a line exchanging through hole 51. The second scanning sub-line SN12 is not electrically connected to an auxiliary signal line 32. In other embodiments, the second scanning sub-line SN12 is electrically connected to an auxiliary signal line 32 through a line exchanging through hole 51, and the first scanning sub-line SN11 is not electrically connected to an auxiliary signal line 32.

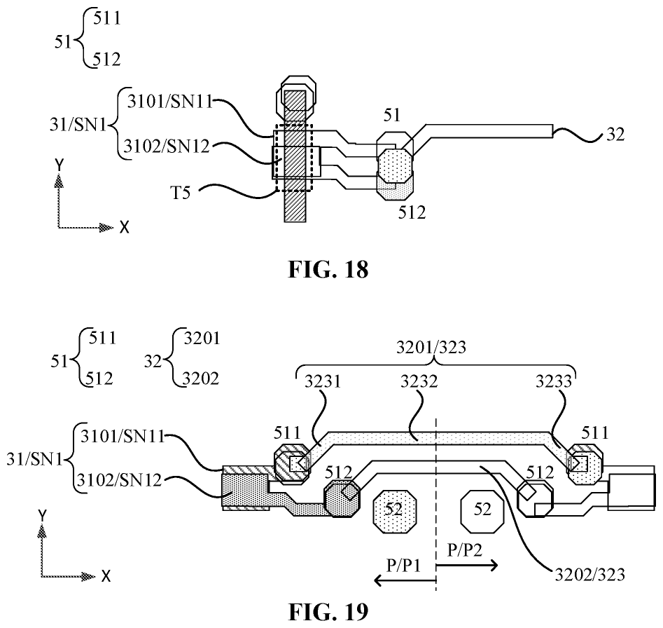

FIG. 18 is a diagram illustrating a partial structure of another pixel driving circuit according to an embodiment of the present disclosure. Referring to FIG. 18, the first signal sub-line 3101 and the second signal sub-line 3102 are electrically connected to the same auxiliary signal line 32.

Illustratively, as shown in FIG. 18, the first scanning sub-line SN11 is electrically connected to the auxiliary signal line 32 through a line exchanging through hole 51. The second scanning sub-line SN12 is electrically connected to the auxiliary signal line 32 through a line exchanging through hole 51. The first scanning sub-line SN11 and the second scanning sub-line SN12 are electrically connected to the same auxiliary signal line 32.

Still referring to FIG. 16, the auxiliary signal lines 20 include a first auxiliary signal sub-line 3201 and a second auxiliary signal sub-line 3202 which are disposed at intervals from each other. The first auxiliary signal sub-line 3201 and the second auxiliary signal sub-line 3202 are arranged in the second direction Y. Line exchanging through holes 51 include a first line exchanging through hole 511 and a second line exchanging through hole 512. The first signal sub-line 3101 is electrically connected to the first auxiliary signal sub-line 3201 through the first line exchanging through hole 511. The second signal sub-line 3102 is electrically connected to the second auxiliary signal sub-line 3202 through the second line exchanging through hole 512. A vertical projection of the first line exchanging through hole 511 on the substrate 10 is misaligned with a vertical projection of the second line exchanging through hole 512 on the substrate 10. In the direction perpendicular to the substrate 10, the first line exchanging through hole 511 does not overlap the second line exchanging through hole 512. The first line exchanging through hole 511 and the second line exchanging through hole 512 are spaced apart. The first line exchanging through hole 511 is not electrically connected to the second line exchanging through hole 512 in the display region 101. Therefore, the first signal sub-line 3101 is not electrically connected to the second signal sub-line 3102 in the display region 101.

Illustratively, as shown in FIG. 16, the first scanning sub-line SN11 is electrically connected to the first auxiliary signal sub-line 3201 through the first line exchanging through hole 511. The second scanning sub-line SN12 is electrically connected to the second auxiliary signal sub-line 3202 through the second line exchanging through hole 512. In the direction perpendicular to the substrate 10, the first line exchanging through hole 511 does not overlap the second line exchanging through hole 512. The first scanning sub-line SN11 is electrically connected to the second scanning sub-line SN12 in the display region 101.

FIG. 19 is a diagram illustrating a partial structure of another pixel driving circuit according to an embodiment of the present disclosure. Referring to FIGS. 15 and 19, the array substrate further includes the data line VDATA and the data line through hole 52. The data line VDATA is connected through the data line through hole 52 to the semiconductor wire 60 that is disposed in a different layer from the data line VDATA. A channel layer 202 is a portion where the semiconductor wire 60 overlaps a gate 201. The array substrate further includes reset signal transmission lines VREF used for transmitting reset signals. The reset signal transmission lines VREF extend in the first direction X. An auxiliary signal line 32 electrically connected to the first signal sub-line 3101 or the second signal sub-line 3102 is a third auxiliary signal line 323. In the second direction Y, the third auxiliary signal line 323 is disposed between a reset signal transmission line VREF and the data line through hole 52. The third auxiliary signal line 323 includes a first auxiliary signal line segment 3231, a second auxiliary signal line segment 3232, and a third auxiliary signal line segment 3233. The first auxiliary signal line segment 3231 is connected to the third auxiliary signal line segment 3233 through the second auxiliary signal line segment 3232. In the second direction Y, the second auxiliary signal line segment 3232 is disposed on one side of a line exchanging through hole 51 facing away from the data line through hole 52. In the second direction Y, the line exchanging through hole 51 is disposed between the second auxiliary signal line segment 3232 and the data line through hole 52. The second auxiliary signal line segment 3232 is a portion of the third auxiliary signal line 323 protruding toward the data line through hole 52. In this embodiment of the present disclosure, the third auxiliary signal line 323 is close to the data line through hole 52, making the third auxiliary signal line 323 relatively close to the data line through hole 52. To avoid the data line through hole 52, the third auxiliary signal line 323 is bent or curved.

Illustratively, referring to FIGS. 15 and 19, in the second direction Y, a first scanning line SN1 is disposed between a reset signal transmission line VREF (specifically, the first reset signal transmission line VREF1) and the data line through hole 52. The first scanning sub-line SN11 is the first signal sub-line 3101. The second scanning sub-line SN12 is the second signal sub-line 3102. The first scanning sub-line SN11 is electrically connected to the first auxiliary signal sub-line 3201 through the first line exchanging through hole 511. The second scanning sub-line SN12 is electrically connected to the second auxiliary signal sub-line 3202 through the second line exchanging through hole 512. The first auxiliary signal sub-line 3201 and the second auxiliary signal sub-line 3202 are each a bent third auxiliary signal line 323. The first auxiliary signal sub-line 3201 and the second auxiliary signal sub-line 320 are each wound around the data line through hole 52.

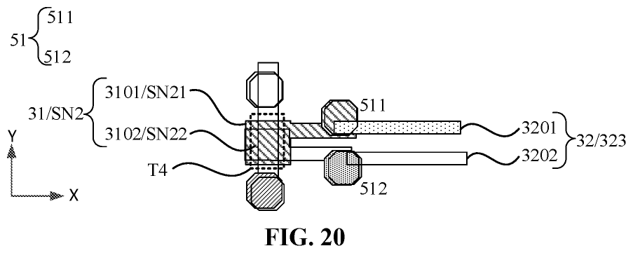

FIG. 20 is a diagram illustrating a partial structure of another pixel driving circuit according to an embodiment of the present disclosure. Referring to FIGS. 15 and 20, the scanning signal lines 31 include the data control signal line SCP1. The data control signal line SCP1 is configured to control a thin-film transistor 21 to transmit a data signal to the first electrode of the drive transistor T3. The pixel driving circuit 20 further includes the storage capacitor C. In the second direction Y, the third auxiliary signal line 323 is disposed between the storage capacitor C and the data control signal line SCP1. The third auxiliary signal line 323 is a straight line segment. Compared with a bend line segment or a curve line segment, a straight line segment is simple in structure and is not easily affected by over-etching, reducing process difficulty.

Illustratively, referring to FIGS. 15 and 20, in the second direction Y, a second scanning line SN2 is disposed between the storage capacitor C and the data control signal line SCP1. The third scan sub-line SN21 is the first signal sub-line 3101. The fourth scan sub-line SN22 is the second signal sub-line 3102. The third scan sub-line SN21 is electrically connected to the first auxiliary signal sub-line 3201 through the first line exchanging through hole 511. The fourth scan sub-line SN22 is electrically connected to the second auxiliary signal sub-line 3202 through the second line exchanging through hole 512. The first auxiliary signal sub-line 3201 and the second auxiliary signal sub-line 3202 are each an unbent third auxiliary signal line 323. The first auxiliary signal sub-line 3201 and the second auxiliary signal sub-line 3202 are each a straight line segment.

Optionally, referring to FIG. 3, 12, or 15, the array substrate further includes the reset signal transmission lines VREF and reset signal auxiliary transmission lines VREF′. The reset signal transmission lines VREF are configured to transmit reset signals. The reset signal transmission lines VREF extend in the first direction X. A reset signal transmission line VREF is disposed in a different layer from a reset signal auxiliary transmission line VREF′, and is electrically connected to the reset signal auxiliary transmission line VREF′ through a connection through hole 53. In the direction perpendicular to the substrate 10, the reset signal auxiliary transmission line VREF′ overlaps a line exchanging through hole 51. Therefore, a light-shielding region of the line exchanging through hole 51 overlaps a light-shielding region of the reset signal auxiliary transmission line VREF′, reducing a common light-shielding area of the line exchanging through hole 51 and the reset signal auxiliary transmission line VREF′ and increasing transmittance.

Illustratively, referring to FIG. 3, the reset signal transmission lines VREF include the first reset signal transmission line VREF1 and the second reset signal transmission line VREF2. The reset signal auxiliary transmission lines VREF′ extend in the second direction Y. The reset signal auxiliary transmission lines VREF′ include a first reset signal auxiliary transmission line VREF3 and a second reset signal auxiliary transmission line VREF4. The first reset signal transmission line VREF1 is electrically connected to the first reset signal auxiliary transmission line VREF3 through a connection through hole 53. The second reset signal transmission line VREF2 is electrically connected to the second reset signal auxiliary transmission line VREF4 through a connection through hole 53. In the direction perpendicular to the substrate 10, the first reset signal auxiliary transmission line VREF3 overlaps a line exchanging through hole 51 at the position of the anode reset control signal line SCP2 and the adjustment control signal line SCP3. In the direction perpendicular to the substrate 10, the second reset signal auxiliary transmission line VREF4 overlaps a line exchanging through hole 51 at the position of the data control signal line SCP1.

Optionally, still referring to FIG. 3, 4, 12, or 15, the thin-film transistors 21 include the drive transistor T3 used for supplying the drive current to the light-emitting element LD. The array substrate further includes a light-shielding line 40. The light-shielding line 40 is disposed between the substrate 10 and the drive transistor T3. The light-shielding line 40 is located in a light-shielding metal layer M0. The light-shielding metal layer M0 is disposed between the silicon semiconductor layer POLY and the substrate 10. The light-shielding line 40 extends in the second direction Y. In the direction perpendicular to the substrate 10, the light-shielding line 40 overlaps a line exchanging through hole 51. Therefore, a light-shielding region of the line exchanging through hole 51 overlaps a light-shielding region of the light-shielding line 40, reducing a common light-shielding area of the line exchanging through hole 51 and the light-shielding line 40 and increasing transmittance.

Illustratively, referring to FIG. 3, in the direction perpendicular to the substrate 10, the light-shielding line 40 overlaps the line exchanging through hole 51 at the position of the anode reset control signal line SCP2.

Illustratively, referring to FIG. 3, in the direction perpendicular to the substrate 10, the light-shielding line 40 overlaps a connection through hole 53. For example, in the direction perpendicular to the substrate 10, the light-shielding line 40 overlaps the connection through hole 53 at the position of the first reset signal transmission line VREF1. Therefore, a light-shielding region of the connection through hole 53 overlaps a light-shielding region of the light-shielding line 40, reducing a common light-shielding area of the connection through hole 53 and the light-shielding line 40 and increasing transmittance.

Illustratively, referring to FIG. 3, in the direction perpendicular to the substrate 10, the light-shielding line 40 overlaps the drive transistor T3 to be used for shield the light projected to the drive transistor T3 from one side of the substrate 10, reducing the effect of a photo-generated carrier on the channel layer 202 of the drive transistor T3.

In some embodiments, no light-shielding line 40 may be provided. The light-shielding metal layer M0 is a newly-added metal layer.

In some embodiments, the light-shielding line 40 extending in the second direction Y may also be replaced with a light-shielding layer. The light-shielding layer is an entire layer but not a line, thereby reducing transmittance. The light-shielding layer has no definite extension direction. In the direction perpendicular to the substrate 10, the light-shielding layer overlaps a plurality of scanning signal lines 31. When the light-shielding layer is used as the auxiliary signal lines 32, only scanning signal lines 31 transmitting the same scanning signal can be electrically connected to each other. Two scanning signal lines 31 transmitting different scanning signals cannot be electrically connected to each other. Moreover, the newly-added light-shielding metal layer M0 increases the thickness of the array substrate.

Optionally, referring to FIGS. 8 and 9, the pixel regions P include the first pixel region P1 and the second pixel region P2 that are disposed adjacent to each other in the first direction X. A junction line LN is formed between the first pixel region P1 and the second pixel region P2. A portion of an auxiliary signal line 32 in the first pixel region P1 is axially symmetric with a portion of the auxiliary signal line 32 in the second pixel region P2 about the junction line LN.

Optionally, referring to FIGS. 8 and 9, a pixel driving circuit 20 located in the first pixel region P0 is a first pixel driving circuit 2001. A pixel driving circuit 20 located in the second pixel region P2 is a second pixel driving circuit 2002. The first pixel driving circuit 2001 is at least partially axially symmetric with the second pixel driving circuit 2002 about the junction line LN. In this embodiment of the present disclosure, the pixel driving circuit 20 adopts a mirror image design.

Illustratively, referring to FIGS. 3 and 8, a storage capacitor C of the first pixel driving circuit 2001 is axially symmetric with a storage capacitor C of the second pixel driving circuit 2002 about the junction line LN. A thin-film transistor 21 (for example, a drive transistor T3) of the first pixel driving circuit 2001 is axially symmetric with a thin-film transistor 21 (for example, a drive transistor T3) of the second pixel driving circuit 2002 about the junction line LN.

Illustratively, referring to FIGS. 3 and 8, a first power line VDD passing through the first pixel region Pl is axially symmetric with a first power line VDD passing through the second pixel region P2 about the junction line LN. A data line VDATA passing through the first pixel region P1 is axially symmetric with a data line VDATA passing through the second pixel region P2 about the junction line LN. A first reset signal auxiliary transmission line VREF3 passing through the first pixel region P0 is axially symmetric with a first reset signal auxiliary transmission line VREF3 passing through the second pixel region P2 about the junction line LN. A second reset signal auxiliary transmission line VREF4 passing through the first pixel region P1 is axially symmetric with a second reset signal auxiliary transmission line VREF4 passing through the second pixel region P2 about the junction line LN. A light-shielding line 40 passing through the first pixel region PI is axially symmetric with a light-shielding line 40 passing through the second pixel region P2 about the junction line LN.

Illustratively, referring to FIGS. 3 and 8, two pixel regions P that are disposed adjacent to each other in the first direction X share the same first power line VDD, thereby not needing to provide two first power lines VDD for the two pixel regions P, reducing the number of first power lines VDD, and increasing transmittance.

Optionally, referring to FIGS. 3 to 5, the array substrate further includes the reset signal transmission lines VREF used for transmitting reset signals. The reset signal transmission lines VREF extend in the first direction X. A reset signal transmission line VREF is in the same layer as the channel layer 202. The reset signal transmission line VREF is in the same layer as the semiconductor wire 60. When the reset signal transmission line VREF is electrically connected to the semiconductor wire 60, no connection through hole needs to be provided for the reset signal transmission line VREF and the semiconductor wire 60, reducing the number of connection through holes and increasing transmittance.

Illustratively, referring to FIGS. 3 to 5, the reset signal transmission lines VREF include the first reset signal transmission line VREF1 and the second reset signal transmission line VREF2. The first reset signal transmission line VREF1 and the second reset signal transmission line VREF2 are each in the same layer as the channel layer 202. The first reset signal transmission line VREF1 and the second reset signal transmission line VREF2 are each located in the silicon semiconductor layer POLY. In the second direction Y, after passing through the second reset transistor T7, the semiconductor wire 60 is directly connected to the second reset signal transmission line VREF2 in the same layer as the semiconductor wire 60, with no need for providing a connection through hole 53 for the second reset signal transmission line VREF2 and the semiconductor wire 60.

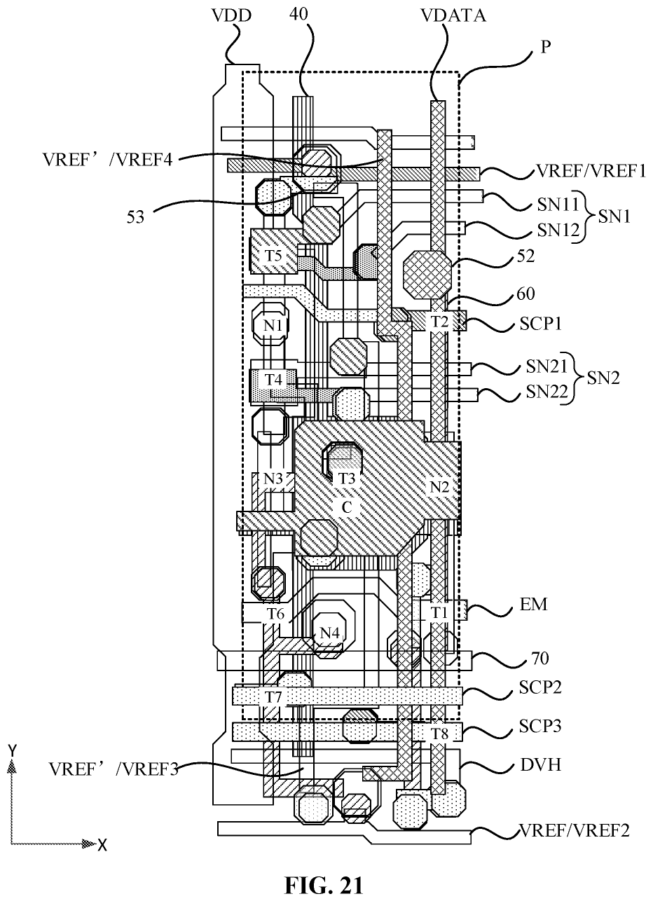

FIG. 21 is a top view of another pixel driving circuit according to an embodiment of the present disclosure. Referring to FIG. 21, the first reset signal transmission line VREF1 is in the same layer as the first plate C1 of the storage capacitor C. The first reset signal transmission line VREF1 is located in the first metal layer M1. The second reset signal transmission line VREF2 is in the same layer as the second plate C2 of the storage capacitor C. The second reset signal transmission line VREF2 is located in the first sub-gate metal layer MC. The resistance of the first metal layer Ml and the resistance of the first sub-gate metal layer MC are each smaller than the resistance of the silicon semiconductor layer POLY, thereby providing better conductivity.

Illustratively, referring to FIG. 21, in the second direction Y, after passing through the second reset transistor T7, the semiconductor wire 60 is electrically connected through a connection through hole 53 to the second reset signal transmission line VREF2 in the different layer from the semiconductor wire 60.

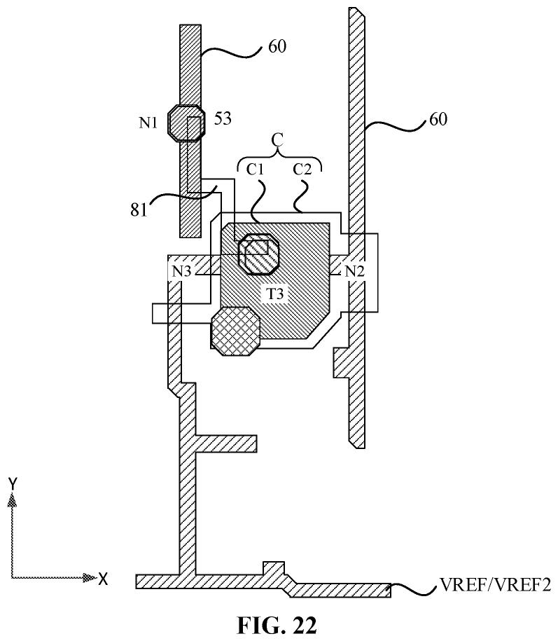

FIG. 22 is a diagram illustrating a partial structure of the pixel driving circuit in FIG. 3. Referring to FIGS. 3, 4, and 22, the pixel driving circuit 20 further includes the storage capacitor C. The storage capacitor C includes the first plate C1 and the second plate C2. The first plate C1 is disposed between the second plate C2 and the substrate 10. The array substrate further includes the semiconductor wire 60, the connection through hole 53, and a connection line 81. At least part of the semiconductor wire 60 extends in the second direction Y. A channel layer 202 is a portion where the semiconductor wire 60 overlaps a gate 201. The channel layer 202 includes an oxide semiconductor material. The semiconductor wire 60 is electrically connected to the connection line 81 through the connection through hole 53. The connection line 81 is in the same layer as an auxiliary signal line 32.

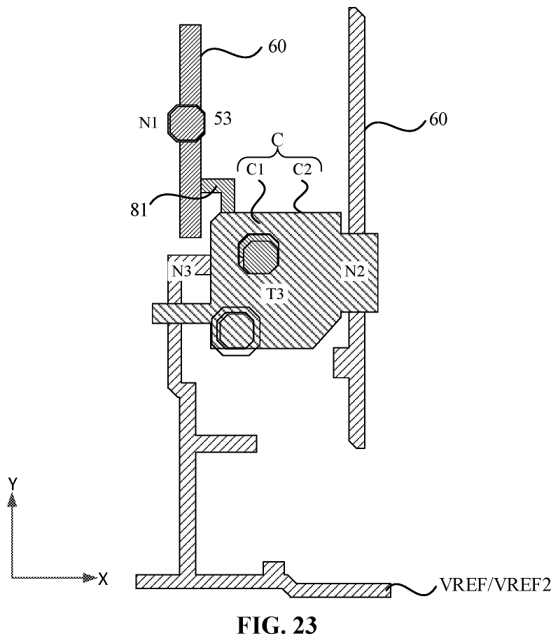

FIG. 23 is a diagram illustrating a partial structure of another pixel driving circuit according to an embodiment of the present disclosure. Referring to FIG. 23, the semiconductor wire 60 connected to the first node N1 is located in the oxide semiconductor layer IGZO. The semiconductor wire 60 located in the oxide semiconductor layer IGZO extends in the second direction Y and is connected to the first plate C1 of the storage capacitor C through the connection line 81. In this embodiment of the present disclosure, the connection line 81 is in the same layer as the first plate C1. Therefore, the connection line 81 is electrically connected to the first plate C1 in the same layer, not needing to provide a connection through hole for the connection line 81 and first plate C1, reducing the number of connection through holes, and increasing transmittance.

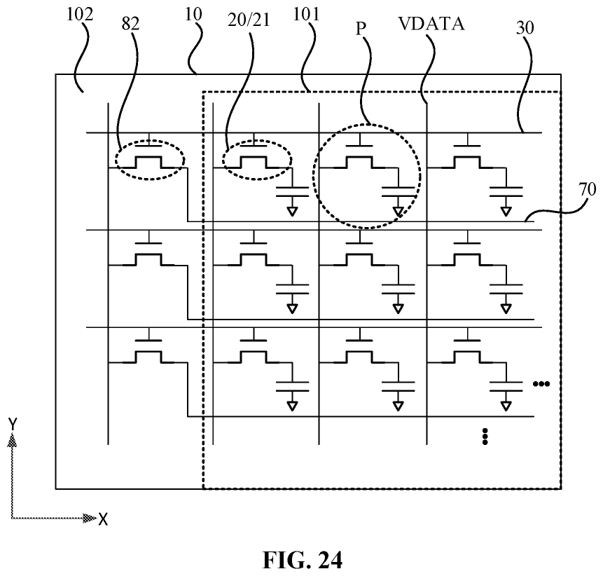

FIG. 24 is a top view of another array substrate according to an embodiment of the present disclosure. Referring to FIGS. 3 and 24, the array substrate further includes a non-display region 102 located at a periphery of the display region 101. The array substrate includes virtual pixel driving circuits 82, repair lines 70, and welding layers 83. The virtual pixel driving circuits 82 are located in the non-display region 102. The repair lines 70 are at least partially located in the display region 101. The repair lines 70 may extend from the display region 101 to the non-display region 102. The repair lines 70 are electrically connected to the virtual pixel driving circuits 82. The welding layers 83 are located in the display region 101. An end of a welding layer 83 is electrically connected to an anode of a light-emitting element LD. In the direction perpendicular to the substrate 10, another end of the welding layer 83 overlaps a repair line 70 in a different layer from the welding layer 83. When a pixel driving circuit 20 in the display region 101 goes wrong, the welding layer 83 and the repair line 70 that overlap each other may be connected together in such a manner as laser welding. Therefore, the anode of the light-emitting element LD is electrically connected to a virtual pixel driving circuit 82 in the non-display region 102. The light-emitting element LD is driven by the virtual pixel driving circuit 82 in the non-display region 102 to emit light.

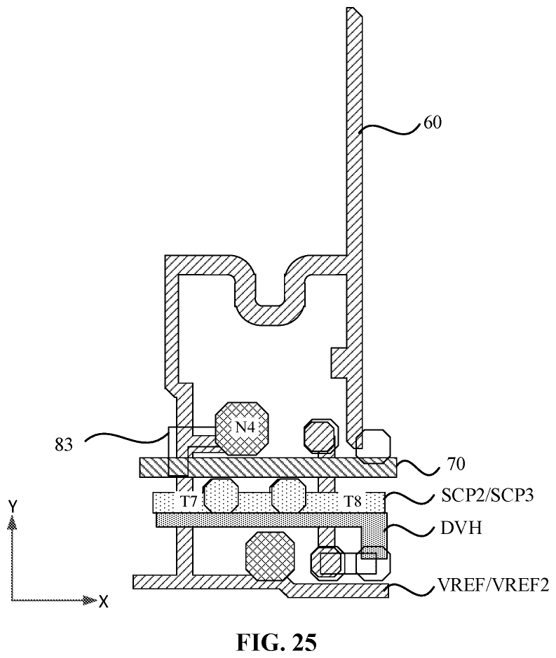

FIG. 25 is a diagram illustrating a partial structure of the pixel driving circuit in FIG. 3. Referring to FIGS. 3, 4, and 25, a thin-film transistor 21 includes a source 203 and a drain 204. The welding layer 83, the source 203, and the drain 204 are in the same layer. The welding layer 83 is in the second metal layer M2. Gates 201 include a first sub-gate 2011 and a second sub-gate 2012. In the direction perpendicular to the substrate 10, the first sub-gate 2011 is disposed between the channel layer 202 and the substrate 10. The second sub-gate 2012 is disposed on one side of the channel layer 202 facing away from the substrate 10. The repair line 70 is in the same layer as the first sub-gate 2011. The repair line 70 is located in the first sub-gate metal layer MC. Therefore, the repair line 70 and the first sub-gate 2011 may be formed in the same process, thereby saving the process.

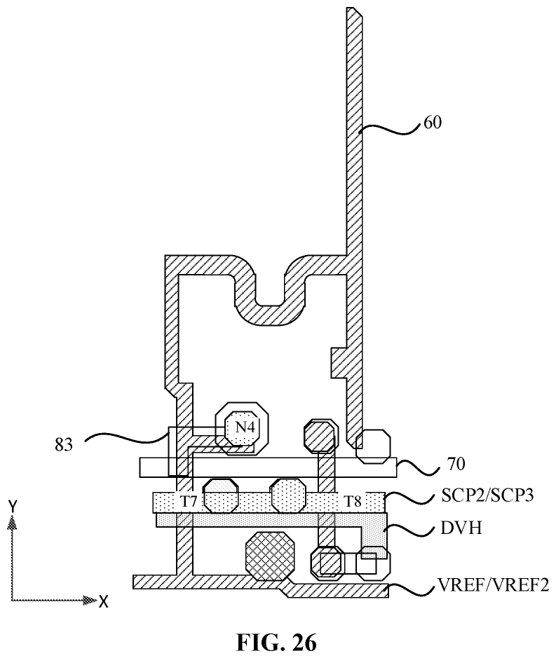

FIG. 26 is a diagram illustrating a partial structure of another pixel driving circuit according to an embodiment of the present disclosure. Referring to FIGS. 4 and 26, the repair line 70 is in the same layer as the second sub-gate 2012. The repair line 70 is located in the second sub-gate metal layer MG. Therefore, the repair line 70 and the second sub-gate 2012 may be formed in the same process, thereby saving the process. Further, in the direction perpendicular to the substrate 10, the repair line 70 is relatively close to the second sub-gate 2012. Therefore, a connection through hole between the repair line 70 and the second sub-gate 2012 may be provided with a relatively small depth, helping simplify the manufacturing process.

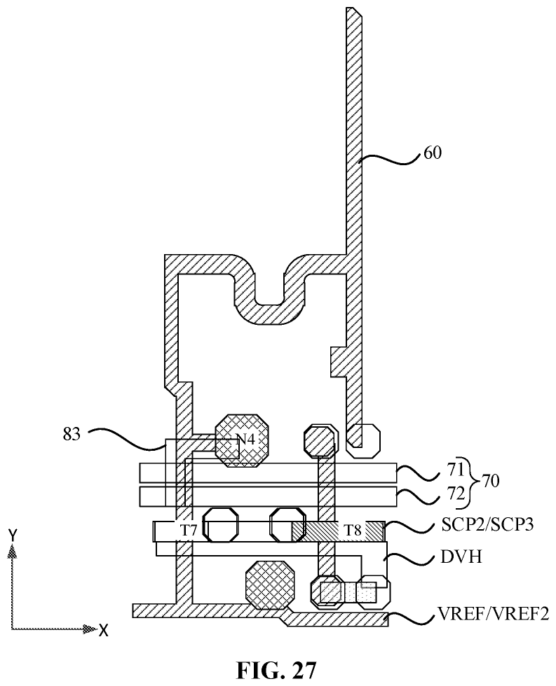

FIG. 27 is a diagram illustrating a partial structure of another pixel driving circuit according to an embodiment of the present disclosure. Referring to FIG. 27, the repair lines 70 include a first repair sub-line 71 and a second repair sub-line 72. The first repair sub-line 71 is in the same layer as the first sub-gate 2011. The first repair sub-line 71 is located in the first sub-gate metal layer MC. The second repair sub-line 72 is in the same layer as the second sub-gate 2012. The second repair sub-line 72 is located in the second sub-gate metal layer

MG. In the direction perpendicular to the substrate 10, the first repair sub-line 71 and the second repair sub-line 72 overlap the same welding layer 83. When the pixel driving circuit 20 in the display region 101 goes wrong, the first repair sub-line 71 and the second repair sub-line 72 may be connected to the same welding layer 83 in such a manner as laser welding. Since two repair lines 70 are provided for the same welding layer 83, the repair rate is increased.

Illustratively, referring to FIG. 27, in the direction perpendicular to the substrate 10, the first repair sub-line 71 is misaligned with the second repair sub-line 72. The first repair sub-line 71 and the second repair sub-line 72 do not overlap each other. Therefore, the overlapping position (that is, the welding position) of the first repair sub-line 71 and the welding layer 83 is misaligned with the overlapping position (that is, the welding position) of the second repair sub-line 72 and the welding layer 83. In this embodiment of the present disclosure, two welding positions are provided with one pixel region P. The two welding positions are provided with two connection through holes respectively. Even if one of the connection through holes goes wrong, the electrical connection of the virtual pixel driving circuit 82 and the light-emitting element LD is not affected, improving the repair rate.

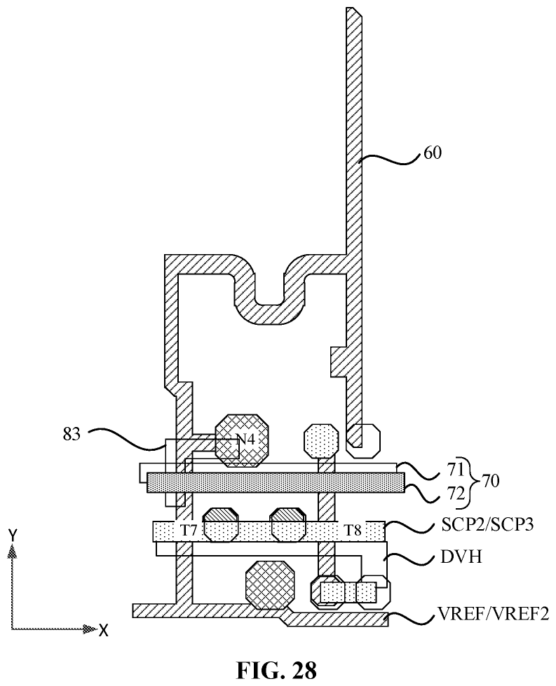

FIG. 28 is a diagram illustrating a partial structure of another pixel driving circuit according to an embodiment of the present disclosure. Referring to FIG. 28, in the direction perpendicular to the substrate 10, the first repair sub-line 71 overlaps the second repair sub-line 72. Any two of the first repair sub-line 71, the second repair sub-line 72, and the welding layer 83 overlap each other.

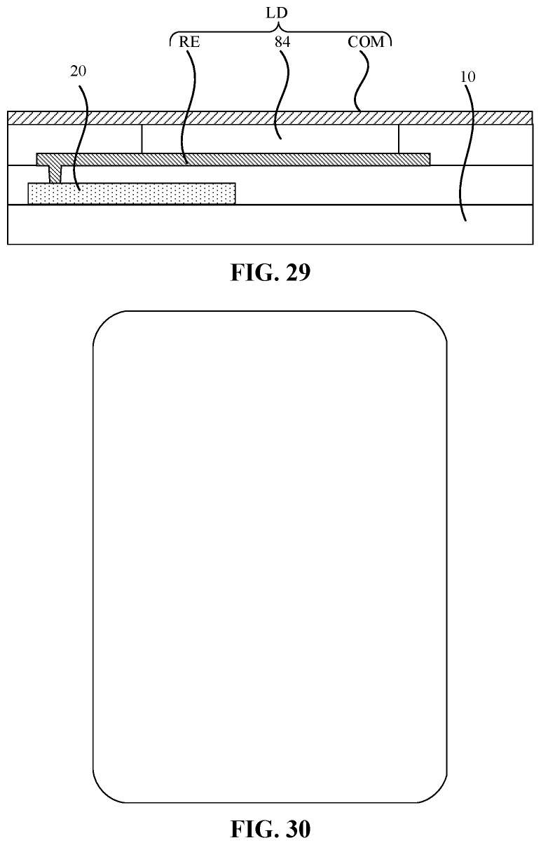

FIG. 29 is a sectional view of a display panel according to an embodiment of the present disclosure. Referring to FIG. 29, the display panel includes the array substrate in any preceding embodiment and a plurality of light-emitting elements LD (one light-emitting element LD is exemplarily illustrated in FIG. 29). A light-emitting element LD is electrically connected to a pixel driving circuit 20 and is configured to be driven by the pixel driving circuit 20 to emit light.

Illustratively, referring to FIG. 29, the light-emitting element LD includes an anode RE, a light-emitting functional layer 84, and a cathode COM. The light-emitting functional layer 84 is disposed between the anode RE and the cathode COM. The light-emitting functional layer 84 may include an organic light-emitting material and/or an inorganic light-emitting material.

FIG. 30 is a diagram of a display apparatus according to an embodiment of the present disclosure. Referring to FIG. 30, the display apparatus includes the display panel described in the preceding embodiments. The display apparatus provided in embodiments of the present disclosure may be a mobile phone or may be any electronic product with a display function, including, but not limited to, a television, a laptop, a desktop display, a tablet computer, a digital camera, a smart bracelet, smart glasses, a vehicle-mounted display, medical equipment, industrial control equipment, and a touch interactive terminal. No special limitations are made thereto in embodiments of the present disclosure.

It is to be noted that the preceding are preferred embodiments of the present disclosure and the technical principles used therein. It is to be understood by those skilled in the art that the present disclosure is not limited to the embodiments described herein. For those skilled in the art, various apparent modifications, adaptations, combinations and substitutions can be made without departing from the scope of the present disclosure. Therefore, while the present disclosure has been described in detail through the preceding embodiments, the present disclosure is not limited to the preceding embodiments and may include equivalent embodiments without departing from the concept of the present disclosure. The scope of the present disclosure is determined by the scope of the appended claims.

What is claimed is:

1. An array substrate, comprising:
a display region comprising a plurality of pixel regions; and
a substrate, pixel driving circuits, and scanning signal lines, wherein at least part of a pixel driving circuit among the pixel driving circuits and at least part of a scanning signal line among the scanning signal lines are located in the display region and on a same side of the substrate, and the scanning signal line extends in a first direction;
wherein at least part of the pixel driving circuit is located in a pixel region among the plurality of pixel regions and comprises thin-film transistors, a thin-film transistor among the thin-film transistors comprises a gate and a channel layer, and the gate is a portion where the scanning signal line overlaps the channel layer; and
wherein the array substrate further comprises auxiliary signal lines, an auxiliary signal line among the auxiliary signal lines is located in the display region and extends in the first direction, a resistance of the auxiliary signal line is smaller than a resistance of the scanning signal line, the auxiliary signal line and the scanning signal line are disposed in different layers, and the auxiliary signal line is electrically connected to the scanning signal line through a line exchanging through hole.

2. The array substrate according to claim 1, wherein a layer where the auxiliary signal line is located is disposed on one side of a layer where the scanning signal line is located facing away from the substrate;
wherein the thin-film transistor comprises a source and a drain; and
the auxiliary signal line, the source, and the drain are disposed in a same layer.

3. The array substrate according to claim 1, wherein in the first direction, a length of the scanning signal line is smaller than a length of the auxiliary signal line.

4. The array substrate according to claim 1, wherein in a direction perpendicular to the substrate, the scanning signal line overlaps the auxiliary signal line in a region other than a region where the line exchanging through hole is located.

5. The array substrate according to 1, wherein a plurality of collinear scanning signal lines among the scanning signal lines are electrically connected to a same auxiliary signal line among the auxiliary signal lines;
wherein the plurality of collinear scanning signal lines comprise a first scanning signal line and a second scanning signal line which are disposed at intervals from each other, and the first scanning signal line and the second scanning signal line are located in a same pixel region among the plurality of pixel regions;
wherein the thin-film transistors comprise a drive transistor used for supplying a drive current to a light-emitting element; and
the first scanning signal line is configured to control a thin-film transistor among the thin-film transistors to transmit a reset signal to an anode of the light-emitting element, and the second scanning signal line is configured to control a thin-film transistor among the thin-film transistors to transmit an adjustment signal to a first electrode of the drive transistor; and
wherein the scanning signal line comprises a first signal line segment and a second signal line segment that are connected to each other, the first signal line segment and the second signal line segment are located in a same pixel region among the plurality of pixel regions, and each of the first signal line segment and the second signal line segment comprises a gate.

6. The array substrate according to claim 5, wherein the plurality of pixel regions comprise a first pixel region and a second pixel region that are disposed adjacent to each other in the first direction; and
the plurality of collinear scanning signal lines comprise a third scanning signal line and a fourth scanning signal line which are disposed at intervals from each other, the third scanning signal line is located in the first pixel region, and the fourth scanning signal line is located in the second pixel region;
wherein the plurality of pixel regions comprise a first pixel region and a second pixel region that are disposed adjacent to each other in the first direction; and
the scanning signal line comprises a third signal line segment and a fourth signal line segment that are connected to each other, the third signal line segment is located in the first pixel region and comprises a gate, and the fourth signal line segment is located in the second pixel region and comprises a gate.

7. The array substrate according to claim 1, wherein a plurality of auxiliary signal lines comprise a first auxiliary signal line and a second auxiliary signal line that are arranged in a second direction, and the second direction intersects the first direction;
the thin-film transistors comprise a drive transistor used for supplying a drive current to a light-emitting element;
a plurality of scanning signal lines comprise a first scanning signal line and a second scanning signal line, the first scanning signal line is configured to control a thin-film transistor among the thin-film transistors to transmit a reset signal to an anode of the light-emitting element, and the second scanning signal line is configured to control a thin-film transistor among the thin-film transistors to transmit an adjustment signal to a first electrode of the drive transistor; and
the first scanning signal line is electrically connected to the first auxiliary signal line, and the second scanning signal line is electrically connected to the second auxiliary signal line.

8. The array substrate according to claim 1, wherein the pixel driving circuit further comprises a storage capacitor; and
a vertical projection of the auxiliary signal line on the substrate and a vertical projection of the storage capacitor on the substrate are arranged in a second direction, and the second direction intersects the first direction;
wherein the thin-film transistors comprise a drive transistor used for supplying a drive current to a light-emitting element;
a plurality of scanning signal lines comprise an anode reset control signal line and an adjustment control signal line, the anode reset control signal line is configured to control a thin-film transistor among the thin-film transistors to transmit a reset signal to an anode of the light-emitting element, and the adjustment control signal line is configured to control a thin-film transistor among the thin-film transistors to transmit an adjustment signal to a first electrode of the drive transistor;
in the second direction, the anode reset control signal line and the adjustment control signal line are located on a same side of the storage capacitor; and
an auxiliary signal line electrically connected to the anode reset control signal line is a straight line segment, and an auxiliary signal line electrically connected to the adjustment control signal line is a straight line segment.

9. The array substrate according to claim 8, wherein the scanning signal lines comprise a data control signal line, and the data control signal line is configured to control a thin-film transistor among the thin-film transistors to transmit a data signal to the first electrode of the drive transistor;
the array substrate further comprises a data line and a data line through hole, the data line is connected through the data line through hole to a semiconductor wire that is disposed in a different layer from the data line, and the channel layer is a portion where the semiconductor wire overlaps the gate;
in the second direction, the data control signal line is disposed on one side of the storage capacitor facing away from the anode reset control signal line, and at least one scanning signal line among the scanning signal lines is disposed between the data control signal line and the data line through hole; and
an auxiliary signal line electrically connected to the data control signal line is a straight line segment;
wherein the array substrate further comprises an adjustment signal transmission line used for transmitting the adjustment signal, wherein the adjustment signal transmission line extends in the first direction;
a layer where the adjustment signal transmission line is located is disposed between a layer where the adjustment control signal line is located and a layer where the auxiliary signal line is located; and
a vertical projection of the adjustment control signal line on the substrate is misaligned with a vertical projection of the adjustment signal transmission line on the substrate.

10. The array substrate according to claim 1, wherein the scanning signal lines comprise a first signal sub-line and a second signal sub-line;
gates comprise a first sub-gate and a second sub-gate; and in a direction perpendicular to the substrate, the first sub-gate is located between the channel layer and the substrate, and the second sub-gate is located on a side of the channel layer facing away from the substrate;
the first sub-gate is a portion where the first signal sub-line overlaps the channel layer, and the second sub-gate is a portion where the second signal sub-line overlaps the channel layer; and
the first signal sub-line and/or the second signal sub-line is electrically connected to the auxiliary signal line through the line exchanging through hole.

11. The array substrate according to claim 10, wherein the auxiliary signal lines comprise a first auxiliary signal sub-line and a second auxiliary signal sub-line which are disposed at intervals from each other;
line exchanging through holes comprise a first line exchanging through hole and a second line exchanging through hole, the first signal sub-line is electrically connected to the first auxiliary signal sub-line through the first line exchanging through hole, and the second signal sub-line is electrically connected to the second auxiliary signal sub-line through the second line exchanging through hole; and
a vertical projection of the first line exchanging through hole on the substrate is misaligned with a vertical projection of the second line exchanging through hole on the substrate.

12. The array substrate according to claim 10, further comprising a data line and a data line through hole, wherein the data line is connected through the data line through hole to a semiconductor wire that is disposed in a different layer from the data line, and the channel layer is a portion where the semiconductor wire overlaps the gate;
the array substrate further comprises reset signal transmission lines used for transmitting reset signals, wherein the reset signal transmission lines extend in the first direction;
an auxiliary signal line electrically connected to the first signal sub-line or the second signal sub-line is a third auxiliary signal line; in a second direction, the third auxiliary signal line is disposed between a reset signal transmission line among the reset signal transmission lines and the data line through hole; and the second direction intersects the first direction; and
the third auxiliary signal line comprises a first auxiliary signal line segment, a second auxiliary signal line segment, and a third auxiliary signal line segment;
the first auxiliary signal line segment is connected to the third auxiliary signal line segment through the second auxiliary signal line segment; and in the second direction, the second auxiliary signal line segment is disposed on one side of the line exchanging through hole facing away from the data line through hole.

13. The array substrate according to claim 10, wherein the scanning signal lines comprise a data control signal line, and the data control signal line is configured to control a thin-film transistor among the thin-film transistors to transmit a data signal to a first electrode of a drive transistor;
the pixel driving circuit further comprises a storage capacitor;
an auxiliary signal line among the auxiliary signal lines and electrically connected to the first signal sub-line or the second signal sub-line is a third auxiliary signal line; in a second direction, the third auxiliary signal line is disposed between the storage capacitor and the data control signal line; and the second direction intersects the first direction; and
the third auxiliary signal line is a straight line segment.

14. The array substrate according to claim 1, further comprising reset signal transmission lines and reset signal auxiliary transmission lines, wherein
the reset signal transmission lines are configured to transmit reset signals and extend in the first direction, a reset signal transmission line among the reset signal transmission lines is disposed in a different layer from a reset signal auxiliary transmission line among the reset signal auxiliary transmission lines, and the reset signal transmission line is electrically connected to the reset signal auxiliary transmission line through a connection through hole; and
in a direction perpendicular to the substrate, the reset signal auxiliary transmission line overlaps the line exchanging through hole.

15. The array substrate according to claim 1, wherein the thin-film transistors comprise a drive transistor used for supplying a drive current to a light-emitting element;
the array substrate further comprises a light-shielding line; the light-shielding line is disposed between the substrate and the drive transistor; and in a second direction, the second direction intersects the first direction; and
in a direction perpendicular to the substrate, the light-shielding line overlaps the line exchanging through hole.

16. The array substrate according to claim 1, wherein the plurality of pixel regions comprise a first pixel region and a second pixel region that are disposed adjacent to each other in the first direction, and a junction line is formed between the first pixel region and the second pixel region; and
a portion of the auxiliary signal line in the first pixel region is axially symmetric with a portion of the auxiliary signal line in the second pixel region about the junction line;
wherein a pixel driving circuit located in the first pixel region is a first pixel driving circuit, and a pixel driving circuit located in the second pixel region is a second pixel driving circuit; and
at least a portion of the first pixel driving circuit is axially symmetric with the second pixel driving circuit about the junction line.

17. The array substrate according to claim 1, wherein the pixel driving circuit further comprises a storage capacitor, the storage capacitor comprises a first plate and a second plate, and the first plate is disposed between the second plate and the substrate;
the array substrate further comprises a semiconductor wire, a connection through hole, and a connection line;
at least part of the semiconductor wire extends in a second direction, the channel layer is a portion where the semiconductor wire overlaps the gate, and the channel layer comprises an oxide semiconductor material; and
the semiconductor wire is electrically connected to the connection line through the connection through hole, and the connection line is disposed in a same layer as the first plate.

18. The array substrate according to claim 1, further comprising a non-display region located at a periphery of the display region; and
virtual pixel driving circuits, repair lines, and welding layers, wherein the virtual pixel driving circuits are located in the non-display region, and at least a part of the repair lines are located in the display region and are electrically connected to the virtual pixel driving circuits;
wherein the welding layers are located in the display region, an end of a welding layer among the welding layers is electrically connected to an anode of a light-emitting element;
and in a direction perpendicular to the substrate, another end of the welding layer overlaps a repair line among the repair lines and in a different layer from the welding layer;
wherein the thin-film transistor comprises a source and a drain; and the welding layer, the source, and the drain are disposed in a same layer;
gates comprise a first sub-gate and a second sub-gate; and in the direction perpendicular to the substrate, the first sub-gate is disposed between the channel layer and the substrate, and the second sub-gate is disposed on one side of the channel layer facing away from the substrate;
a repair line among the repair lines is disposed in a same layer as the first sub-gate; or a repair line among the repair lines is disposed in a same layer as the second sub-gate; or
the repair lines comprise a first repair sub-line and a second repair sub-line, the first repair sub-line is disposed in a same layer as the first sub-gate, and the second repair sub-line is disposed in a same layer as the second sub-gate.

19. A display panel, comprising an array substrate and a plurality of light-emitting elements; wherein the array substrate comprises:
a display region comprising a plurality of pixel regions; and
a substrate, pixel driving circuits, and scanning signal lines, wherein at least part of a pixel driving circuit among the pixel driving circuits and at least part of a scanning signal line among the scanning signal lines are located in the display region and on a same side of the substrate, and the scanning signal line extends in a first direction;
wherein at least part of the pixel driving circuit is located in a pixel region among the plurality of pixel regions and comprises thin-film transistors, a thin-film transistor among the thin-film transistors comprises a gate and a channel layer, and the gate is a portion where the scanning signal line overlaps the channel layer;
wherein the array substrate further comprises auxiliary signal lines, an auxiliary signal line among the auxiliary signal lines is located in the display region and extends in the first direction, a resistance of the auxiliary signal line is smaller than a resistance of the scanning signal line, the auxiliary signal line and the scanning signal line are disposed in different layers, and the auxiliary signal line is electrically connected to the scanning signal line through a line exchanging through hole; and
a light-emitting element among the plurality of light-emitting elements is electrically connected to a pixel driving circuit and is configured to be driven by the pixel driving circuit to emit light.

20. A display apparatus, comprising the display panel according to claim 19.
